(19) United States
(12) Patent Application Publication
(10) Pub. No.: US 2016/0172512 A1
(43) Pub. Date: Jun. 16, 2016

(54) LAMINATED BACKPLANE FOR SOLAR CELLS

(71) Applicant: SOLEXEL, INC., Milpitas, CA (US)

(72) Inventors: Thom Stalcup, Milpitas, CA (US); Mehrdad M. Moslehi, Los Altos, CA (US); Pawan Kapur, Burlingame, CA (US); Manteghi Kamran, Milpitas, CA (US); David Dutton, Milpitas, CA (US)

(21) Appl. No.: 14/903,273

(22) PCT Filed: Jul. 30, 2014
(86) PCT No.: PCT/US14/48989

§ 371 Date: Jan. 6, 2016

Related U.S. Application Data
(63) Continuation-in-part of application No. 13/807,631, filed on Sep. 11, 2014.
Application No. 13/807,631 is a continuation-in-part of application No. 13/433,280, filed on Mar. 28, 2012.
Application No. 13/433,280 is a continuation-in-part of application No. 13/204,626, filed on Aug. 5, 2011, now Pat. No. 8,946,547.
(60) Provisional application No. 61/521,754, filed on Aug. 9, 2011.
(60) Provisional application No. 61/521,743, filed on Aug. 9, 2011.
(60) Provisional application No. 61/468,548, filed on Mar. 28, 2011.
(60) Provisional application No. 61/370,956, filed on Aug. 5, 2010.
(60) Provisional application No. 61/860,216, filed on Jul. 30, 2013.

(51) Int. Cl. H01L 31/0224

(52) U.S. Cl. CPC H01L 31/022441

(57) ABSTRACT

A back contact solar cell structure having a light receiving frontside and a metallized backside of on-cell patterned base and emitter metallization electrically connected to base and emitter regions on a back contact solar cell semiconductor substrate. A backplane laminate layer made of resin and fibers and having a coefficient of thermal expansion relatively matched to the back contact solar cell semiconductor substrate is attached to the on-cell base and emitter metallization and to portions of the back contact solar cell semiconductor substrate not covered by the on-cell base and emitter metallization.

### CROSS-REFERENCE TO RELATED APPLICATIONS

This application claims the benefit of U.S. provisional patent application 61/860,216 filed on Jul. 30, 2013 which is hereby incorporated by reference in its entirety.

This application is also a continuation-in-part of U.S. patent application Ser. No. 13/807,631 filed Dec. 28, 2012 which is a national stage entry of PCT/US12/00348 filed Aug. 9, 2012 which claims the benefit of U.S. Provisional Pat. App. No. 61/521,743 filed Aug. 9, 2011 and U.S. Provisional Pat. App. No. 61/521,754 filed Aug. 9, 2011 all of which are hereby incorporated by reference in their entirety.

This application is also a continuation-in-part of U.S. patent application Ser. No. 13/433,280 filed Mar. 28, 2012 which claims the benefit of U.S. Provisional Pat. App. No. 61/468,548 filed Mar. 28, 2011 and which is a continuation-in-part of U.S. patent application Ser. No. 13/204,626 filed Aug. 5, 2011 which claims the benefit of U.S. Provisional Pat. App. No. 61/370,956 filed Aug. 5, 2010 all of which are hereby incorporated by reference in their entirety.

### FIELD OF THE INVENTION

This disclosure relates in general to the field of solar cells, and more particularly to backplane attached solar cells.

### BACKGROUND

Currently, crystalline silicon (both multi-crystalline and mono-crystalline silicon) has the largest market share in the photovoltaics (PV) industry, currently accounting for about 85% of the overall global PV market share. Although moving to thinner crystalline silicon solar cells is long understood to be one of the most potent and effective methods for PV cost reduction (because of the relatively high material cost of crystalline silicon wafers used in solar cells as a fraction of the total PV module cost), utilizing thinner crystalline wafers is hampered by the problem of thin wafers being extremely fragile, mechanical breakage during wafer handling and cell processing, and the resulting production yield losses caused by thin and fragile silicon wafers.

And while thin crystalline solar cells may benefit from a permanent backplane support, solar cell fabrication processing often include high temperature processing which increase mechanical stresses on thin silicon solar cell substrates and emphasizes difficulties relating to thermal expansion mismatches, adhesion imperfections, etc. Current solar cells often include solar cell packages, encapsulants, modules, and sealing sheets for protecting and supporting a solar cell in the field but which lack inherent structural characteristics for use as permanently attached layers bonded to the solar cell absorber itself for support during cell processing and throughout the solar cell field use lifetime.

### SUMMARY

Therefore a need has arisen for solar cell backplanes attached back contact solar cells which provide enhanced structural support for back contact solar cells. In accordance with the disclosed subject matter, backplane attached back contact solar cells are provided which substantially eliminate or reduces disadvantage and problems associated with previously developed solar cells.

According to one aspect of the disclosed subject matter, a back contact solar cell structure having a light receiving frontside and a metallized backside is provided. On-cell patterned base and emitter metallization is electrically connected to base and emitter regions on a back contact solar cell semiconductor substrate. A backplane laminate layer made of resin and fibers and having a coefficient of thermal expansion relatively matched to the back contact solar cell semiconductor substrate is attached to the on-cell base and emitter metallization and to portions of the back contact solar cell semiconductor substrate not covered by the on-cell base and emitter metallization.

These and other aspects of the disclosed subject matter, as well as additional novel features, will be apparent from the description provided herein. The intent of this summary is not to be a comprehensive description of the claimed subject matter, but rather to provide a short overview of some of the subject matter's functionality. Other systems, methods, features and advantages here provided will become apparent to one with skill in the art upon examination of the following FIGUREs and detailed description. It is intended that all such additional systems, methods, features and advantages that are included within this description, be within the scope of any claims.

### BRIEF DESCRIPTION OF THE DRAWINGS

The features, natures, and advantages of the disclosed subject matter may become more apparent from the detailed description set forth below when taken in conjunction with the drawings in which like reference numerals indicate like features and wherein:

FIG. 1 is a cross-sectional diagram of a backplane attached back contact solar cell comprising a backplane layer having a fiber and a resin content;

FIG. 2 is a cross-sectional diagram of a dual level backplane attached back contact solar cell;

FIG. 3 is a cross-sectional diagrams of a two-level metallization backplane attached back contact solar cell comprising a backplane layer having a fiber and a resin content;

FIG. 4 is a cross-sectional diagram of a two-level metallization dual level backplane attached back contact solar cell;

FIG. 5 is a photograph of woven aramid fiber substrate at twenty times magnification;

FIG. 6 is a photograph of non-woven aramid fiber substrate at twenty times magnification;

FIG. 7 is a graph showing data for Coefficient of Thermal Expansion or CTE vs. Resin Content for the aramid fiber prepreg material;

FIG. 8 is a rheology graph outlining the rheology profile for a blended resin system;

FIG. 9 is a diagram illustrating coupling of the silane to silicon oxide and diffusion of the additive within the resin;

FIGS. 10A, 10B, and 10C are graphs showing a lamination process profile of a blended resin system;

FIG. 11 is a graph illustrating the outcome of a series of tests run on samples with blended resin;

FIGS. 12A and 12B are SEM photographs highlighting voids in the solar cell structure occurring during a non-vacuumed lamination;

FIG. 13 is a high level solar cell and module fabrication process flow embodiment using starting crystalline (mono-crystalline or multi-crystalline) silicon wafers; and

FIG. 14 is a cross-sectional diagram of a backplane attached back contact solar cell in accordance with the disclosed subject matter.

### DETAILED DESCRIPTION

The following description is not to be taken in a limiting sense, but is made for the purpose of describing the general principles of the present disclosure. The scope of the present disclosure should be determined with reference to the claims. Exemplary embodiments of the present disclosure are illustrated in the drawings, like numbers being used to refer to like and corresponding parts of the various drawings. Importantly, the exemplary dimensions and calculations disclosed for embodiments are provided both as detailed descriptions for specific embodiments and to be used as general guidelines when forming and designing solar cells in accordance with the disclosed subject matter.

The present application provides unique support solutions for supporting large area (e.g., with areas in the range of about 100 cm2 up to several square meters), thin (e.g., in the thickness range of about a few microns up to 100's of microns), brittle materials using prepreg backplane structures comprising resin and fiber. The disclosed organic or polymeric backplane structures and fabrication methods were developed particularly for coefficient of thermal explanation (CTE) matching with semiconductor materials such as crystalline silicon for solar cells used in high efficiency solar cells.

Innovative backplane and lamination process characteristics of the backplane (for applications including but not limited to high-efficiency solar cells) are provided, including fabrication implementation materials and method descriptions for those having ordinary skill in the art. And although the present disclosure is described with reference to specific embodiments, such as interdigitated back-contact (IBC) solar cells using monocrystalline silicon substrates and other described fabrication materials, one skilled in the art could apply the principles discussed herein to other solar cells including but not limited to non-IBC back-contact solar cells (such as Metallization Wrap-Through or MWT back-contact solar cells, traditional front contact cells, other fabrication materials including alternative semiconductor materials (such as materials comprising one or a combination of silicon, gallium arsenide, germanium, gallium nitride, other binary and ternary semiconductors, etc.), technical areas, and/or embodiments without undue experimentation.

The innovative material characteristics and processing requirements of the backplane are used for the manufacture of flexible semiconductor electronics and photovoltaics devices and are particularly advantageous for high-efficiency crystalline silicon solar cells. Exemplary design rules were developed in support of back-contact/back-junction crystalline silicon solar cells, including those made either by epitaxially grown mono-crystalline silicon or from crystalline silicon wafers made using CZ or cast multi-crystalline wafers. However, it should be understood that the embodiments provided herein are also applicable to other crystalline semiconductor solar cells and modules.

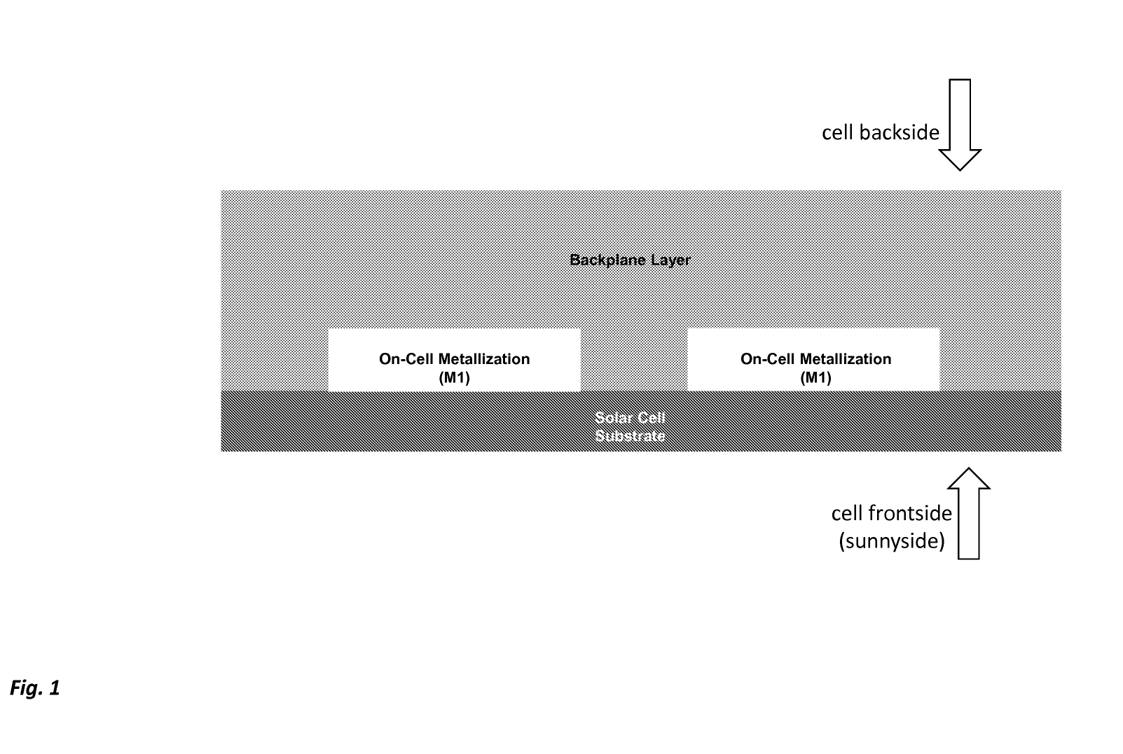

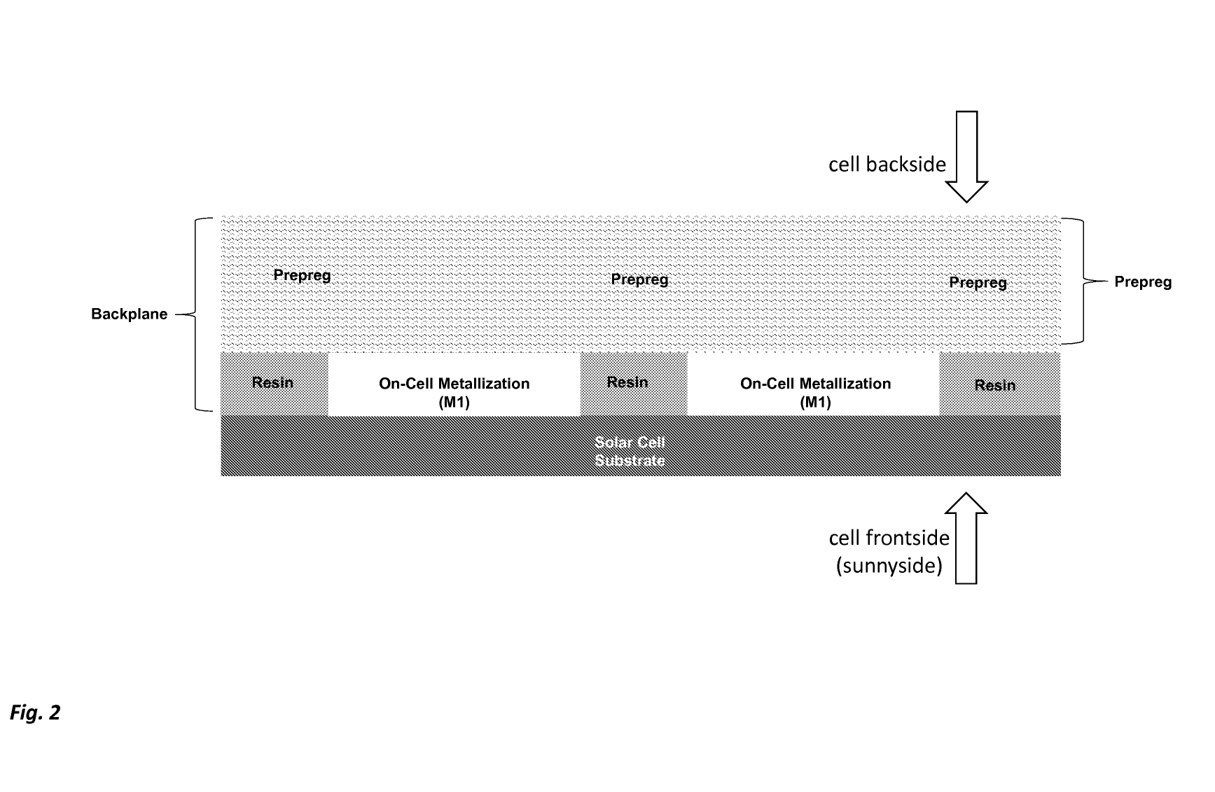

In one of the simplest embodiments, the backplane may be single component (relatively thin flexible sheet of a suitable material) which is directly attached (e.g., bonded) to thin (for instance, in the thickness range of about a few microns up to 250 microns) silicon wafers or silicon substrates (or other semiconductor materials such as GaAs, GaN, etc.). FIG. 1 is a cross-sectional diagram of a backplane attached back contact solar cell comprising a backplane layer having a fiber and a resin content. FIG. 2 is a cross-sectional diagram of a dual level backplane attached back contact solar cell. The descriptions provided focus on application to back-contact/back-junction solar cells using thin crystalline silicon absorbers; however, it should be understood that the embodiments of this invention are applicable to various other solar cell designs (such as front-contact solar cells) and other semiconductor absorber materials.

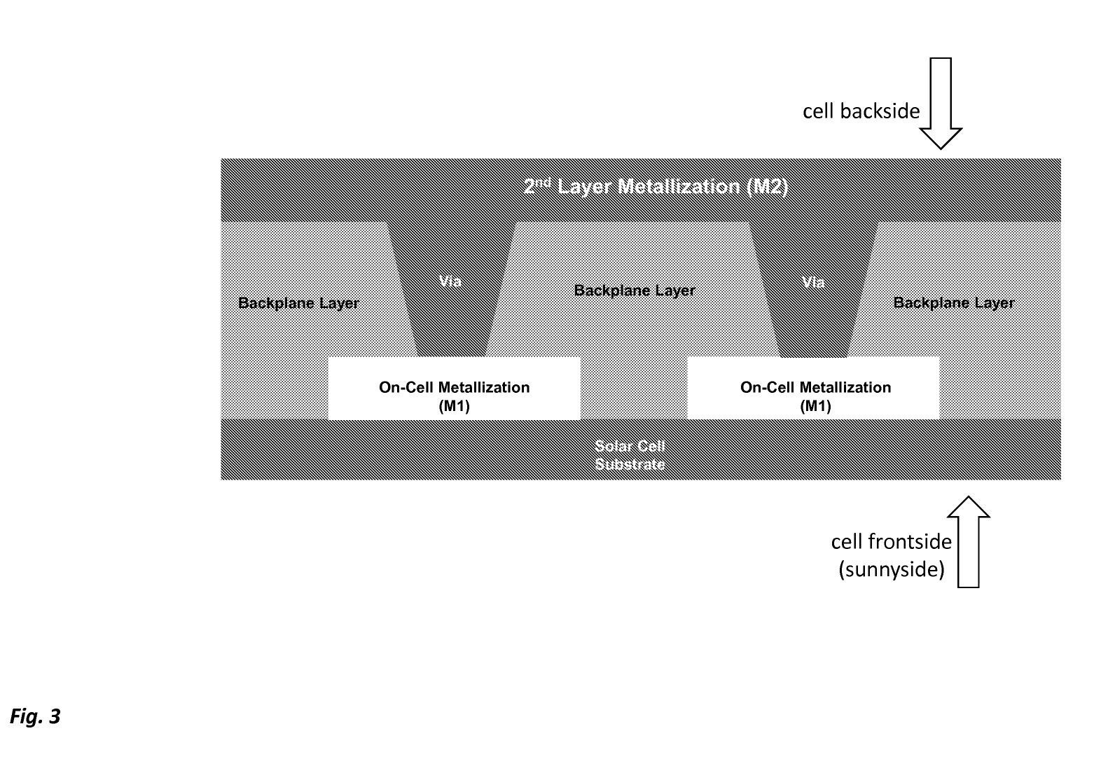

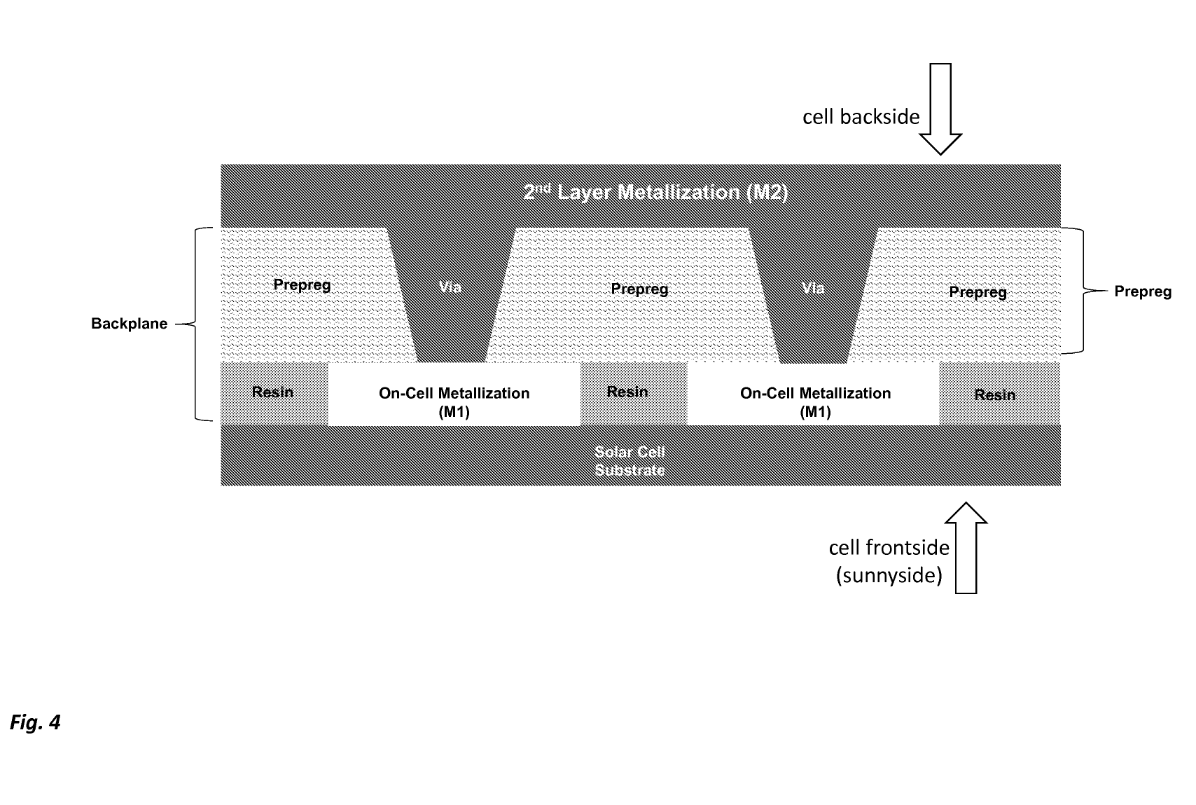

The backplane structure may fulfill two primary functions. First, it is a structural support across the full area of the wafer or thin semiconductor absorber providing mechanical strength sufficient for a wafer or thin solar cell absorber to be handled and processed without damage or breakage and which may be subsequently laminated in the final solar cell module without damage or breakage. Second, the backplane serves as a dielectric or electrically insulating layer through which connections may be made between a cell-level contact metallization (referred to herein as Metal-1, M1, or on-cell metallization) on the silicon wafer or substrate (on-cell) and a second or final higher conductivity metallization (referred to herein as Metal-2 or M2) used for extracting the solar cell power and interconnections with other solar cells into a module. Thus, the backplane enables implementation of a two-level metallization architecture for the back-contact/back-junction solar cell for low-cost manufacturing of high-efficiency solar cells and modules. FIG. 3 is a cross-sectional diagrams of a two-level metallization backplane attached back contact solar cell comprising a backplane layer having a fiber and a resin content. FIG. 4 is a cross-sectional diagram of a two-level metallization dual level backplane attached back contact solar cell. The disclosed subject matter relates directly to prepreg backplane supported back contact solar cells and fabrication as provided herein and those detailed in U.S. patent application Ser. No. 13/433,280 filed Mar. 28, 2012 published as U.S. 2009/0000715 on Jan. 3, 2013, 13/807,631 filed Dec. 28, 2012 published as PCT Pub. No. WO 2013022479 on Feb. 14, 2013, 13/822,657 filed Apr. 2, 2013 published as U.S. 2013/0213469 on Aug. 22, 2013, and 13/869,928 filed Apr. 24, 2013 published as U.S. 2013/0228221 on Sep. 5, 2013 which are all hereby incorporated by reference in their entirety.

Additionally, and optionally, the backplane structure as a thermally and mechanically decoupling structure from the solar cell substrate may enable placement of power semiconductor electronics components per solar cell for various cell-level applications—for example a rectifier switch for distributed shade management and maximum-power-point tracking (MPPT) power optimizer to extract the maximum power from the solar cell under various operating conditions in the field.

In accordance with the disclosed subject matter, the backplane is a resin-impregnated fiber substrate (typically in the thickness range of approximately 25 microns up to about 250 microns, and more particularly in the range of 75 microns to 150 microns depending on desired flexibility among other considerations) that is laminated directly to the backside of the thin silicon wafer or solar cell absorber. Thus providing a simple, robust, reliable, and cost effective solar cell design. FIGS. 1 and 2 are cross-sectional diagrams of a backplane attached back contact solar cell.

The following design considerations were established for creation and assessment of a backplane and are provided herein for use as detailed design requirements and guidelines for backplane material selection and testing. The primary backplane embodiments provided herein meet primary design objectives for full end use product certification and product commercialization. The range of suitable materials for a backplane to support thin (e.g., in the thickness range of a few microns up to 250 microns) solar cell semiconductor absorber materials may be defined by a series of requirements (both essential and optional requirements) ensuring compatibility with end use solar cell application and solar cell/module manufacturing processes. Boundary conditions help define material selection, material development, and engineering evaluation processes. High level criteria for the backplane materials and implementation may include, but are not limited to, the following combination of critical and optional criteria:
An adhesive system to adhere (i.e., bond) well to a wide range of different materials used for solar cell substrates and passivation, metallization, and module encapsulants, including for example: silicon, silicon oxide, aluminum, aluminum oxide, aluminum/silicon fired paste, fritted aluminum fired paste, tin, and the module encapsulant such as ethylene vinyl acetate (EVA) or polyolefin or any other encapsulant material used for module lamination. Improved adhesion mitigations and prevents the risk of delamination of the backplane after the lamination process.
All constituent backplane materials should be compatible with various environments in a solar cell manufacturing flow (depending on the solar cell process flow). Solar cell process environments include for example; high vacuum, rapid thermal ramp, plasma etching, thermal anneal (for instance, up to about 300° C.), wet processing (such as wet silicon etching, texturing, cleaning, and/or metal plating, if such wet processes are used after the backplane lamination during the solar cell fabrication process for example). For example, in some instances a solar cell process flows may not require post-lamination wet processing and that particular environmental compatibility requirement would not apply to those specific process flows.
All constituent backplane materials should support relatively high processing temperatures, for instance up to about 250° C. to 300° C. In some cases the backplane should be designed with no resin thermal decomposition at processing temperatures of up to at least 350° C.
All constituent backplane materials should have reasonable or sufficient thermal conductivity to facilitate heat sinking of thermalized energy away from the solar cell absorber layer.
All constituent backplane materials should compatible with laser cutting and drilling if required (for instance, to enable laser trimming of the backplane after lamination, as necessary, and to enable laser drilling of the via holes through the laminated backplane sheet for M2-M1 conductive via plugs formed by the patterned M2 formation).
Total backplane system must have a CTE matching or relatively close to the CTE of the semiconductor substrate, for instance crystalline silicon in the case of crystalline silicon solar cells having a CTE of approximately 2.6 to 2.8 ppm/° C. In other words, the average CTE through the backplane thickness or the expansion control layers of the backplane should have a relative CTE match with the semiconductor substrate. Further, CTE matching, in the case of two level metallization, is particularly important for via protection.
All constituent backplane materials should be non-reactive with wet chemistries if required for solar cell processing. Wet chemistries include, for example; acids, bases, solvents and oxidizers. Again, dependent on solar cell processing methods required or chosen, this requirement may not apply or may be relaxed when cell fabrication process flow embodiments do not use post-lamination wet processing (for example if all wet processes having been performed prior to the solar cell backplane lamination).
Total backplane system should have contained resin flow as contained resin flow may help prevent long-range resin flow.
Total backplane system must provide relatively flat cells, for example with less than ±3 mm center-to-edge substrate bow/warpage, during and after backplane lamination. Low cell bow facilitates post-lamination solar cell processing to complete fabrication of the solar cells and subsequent high-yield lamination of the resulting backplane-attached solar cells into solar modules.
Total backplane system should be relatively dimensionally stable during temperature ramping, for example, up from approximately 20° C. to approximately 250° C. and down from approximately 250° C. to approximately 20° C. with little to no change in relative planarity or flatness.
Total backplane system should be a dielectric or relatively electrically insulating and may serve as an effective electrically insulating layer between solar cell metallization layers (for example to enable two-level solar cell metallization structure with M1-M2 stack).
Total backplane system should be at least partially transparent in the IR spectrum for laser processing (e.g., laser cutting).
Total backplane system should enable enhanced cell and module aesthetic designs. A consideration particularly important for applications which benefit from aesthetically appealing looks of solar cells and modules such as residential or automotive rooftop and portable/transportable solar power applications.
Total backplane system should meet the field lifetime requirement for solar modules, typically at least 25 year field lifetime for solar panels in the field.
Total backplane system should be cost effective, for example having backplane sheet material costs approximately $0.04 per watt or less.

The backplane solutions provided utilize a resin system as an adhesive/binder in a backplane material that ties the cell structure together after lamination of the backplane sheet to the solar cell substrate. Resin systems available for use include, for example, epoxy, polyimide and blended resins which are all commercially available and each has properties that meet certain of the essential and/or optional criteria for use in the applications of the disclosed subject matter. And while resin is used in combination with a supporting fiber substrate as described herein, there are unique cases where resin only may be used for gap filling—in other words resin is used as a gap filler.

And while high efficiency back-contact/back-junction (also known as interdigitated back-contact or IBC) solar cells with thin crystalline silicon absorbers using backplanes may be manufactured with both epoxy and blended resin systems and either may be used for a viable and cost effective backplane solution when combined with a proper fiber substrate, each material system has certain advantages and disadvantages to consider.

Epoxy based resin systems are common in the Printed Circuit Board (PCB) industry. Epoxy based resin systems may provide a low cost, flexible solution for PCB applications and have demonstrated they can be used effectively in the manufacture of flexible, high-efficiency solar cells. Epoxy is advantageous in providing: generally good adhesion to other solar cell layers, wide lamination process tolerances for lamination temperature and pressure, relatively good chemical resistance, good laser hole drilling uniformity, and the ability to withstand localized heating in traditional soldering processes. However, epoxy disadvantages that may limit the ability of epoxies to fully achieve all the design goals for certain solar cell applications include: significant resin flow during lamination (with resin lateral oozing flow scale much larger than the thickness of the backplane), limited high temperature tolerance, relatively high Coefficient of Thermal Expansion (CTE) of 35 to 45 ppm/° C. (much higher than the CTE of silicon), continued curing (cross linking) of resin post lamination, high moisture absorption, and epoxy resins may require mechanical surface roughening to improve adhesion for some solar cell layer surfaces. Nevertheless, solar cells fabricated with epoxy based resin backplane systems have been proven to meet all reliability requirements in end-use solar cell applications.

Blended resin systems employing high molecular weight resin and thermoset such as a thermoplastics (e.g., organic or synthetic thermoplastic rubbers) are also used in the PCB industry but are less common. Blended resins are often customized for use in specific applications and may provide advantages over for epoxy resins for application to certain flexible high-efficiency solar cells. The blended resin systems provided herein may be a “no flow” material and have a considerably extended temperature operating window—for example a blended resin system having a high molecular weight resin and a thermoset. This blended resin system is advantageous in providing: reset during a reheating, limited resin flow (hence, limited lateral in-plane oozing of the resin) during lamination, high thermal budget capability, low moisture absorption, good adhesion to metal layers in the cell (e.g., to Metal-1 layer such as patterned aluminum contact metallization), lower CTE than epoxy resin, limited additional resin cross linking at elevated temperatures, and good chemical resistance. As with epoxy resins, a no-flow (or low-flow) resin has disadvantages including: an adhesion promoter may be required to achieve adhesion to silicon oxide (the addition of an adhesion promoter may result in chemical compatibility limitations), poor laser via hole drilling uniformity if required, and narrower lamination process windows for temperature and pressure. However, an added benefit of a blended resin system using thermoplastics for in some solar cell backplane applications is that thermoplastic properties of the material allow a fully cured laminate to be heated and reshaped to achieve a specific curvature target in the finished part. High efficiency solar cells fabricated with a blended resin system (e.g. blended with thermoplastics such as thermoplastic rubber) have been fabricated and assembled in module structures with positive results. Further, the use of a blended resin system is among the main embodiments provided herein and a primary path for mass produced high-efficiency solar cells.

And although resin alone may not be a viable solution for solar cell structural support (e.g., support for a thin silicon solar cell) in production, in practice the resin material is impregnated into a fiber substrate and the combination of resin and fiber is used to achieve the desired final backplane material properties—a material called prepreg (the standard PCB industry term for a fiber substrate impregnated with partially cured resin is prepreg). The main silicon solar cell embodiments provided herein use prepreg backplanes with a CTE value equal to or relatively matched to the CTE of the silicon substrate.

Generally, prepregs are reinforcing materials pre-impregnated with resin and ready to use to produce composite parts (prepregs may be used to produce composites faster and easier than wet lay-up systems). Prepregs may be manufactured by combining reinforcement fibers or fabrics with specially formulated pre-catalyzed resins using equipment designed to ensure consistency. Covered by a flexible backing paper, prepregs may be easily handled and remain pliable for a certain time period (out-life) at room temperature. Further, prepreg advances have produced materials which do not require refrigeration for storage, prepregs with longer shelf life, and products that cure at lower temperatures. Prepreg laminates may be cured by heating under pressure. Conventional prepregs are formulated for autoclave curing while low-temperature prepregs may be fully cured by using vacuum bag pressure alone at much lower temperatures. Prepreg sheets are used as building blocks of printed circuit boards and may be made from combinations of resins and CTE-reducing fibers or particles. The prepreg backplane material may be inexpensive, be solar cell substrate CTE mateched (typically with CTE<10 ppm/° C., or with CTE<5 ppm/° C.), thin (for example 50 to 250 microns, and more particularly in the range of about 50 to 150 microns) prepreg sheet which is relatively chemically resistant to texturization chemicals and is thermally stable at temperatures up to at least 180° C. (or as high as at least 280° C.).

Fiber substrates are used to achieve the general mechanical properties of prepreg material. The fibers determine many properties of the lamination including: cured sheet thickness, in plane (X and Y axis) CTE, mechanical strength, and dielectric properties. The fiber substrate may be produced in roll stock allowing prepreg to be manufactured in high volume using continuous roller and dip coating methodologies. Selection of the type of fiber used in the substrate is critical to achieving the final properties of the final prepreg laminate.

Aramid fiber substrates have a niche in the PCB industry in applications requiring low CTE and high completed assembly reliability/lifetime in stressed environmental conditions. The backplane layers provided herein apply the unique and novel combination of aramid fiber and resin with a relatively low resulting prepreg CTE (to match or nearly match that of solar cell absorber layer) as a backplane sheet material for permanent thermal lamination to the solar cell. Aramid fiber has a unique property in that its fibers have a negative CTE (−4.5 ppm/° C.) in the axial direction and a positive CTE in the radial direction. In effect, the fiber decreases in length with increasing temperature. Thus, the prepreg system comprising fiber plus resin may be fine-tuned to achieve specific CTE goals aligned to requirements for the end application (for example for application as backplanes in crystalline semiconductor solar cells). Aramid may be additionally advantageous in that it is compatible with CO2 laser drilling and cutting, a critical requirements in a backplane-attached back-contact solar cell having multi-level metallization such as the M1/M2 metallization embodiments provided herein. Generally, aramid fiber substrates are available as woven and non-woven (paper) substrates.

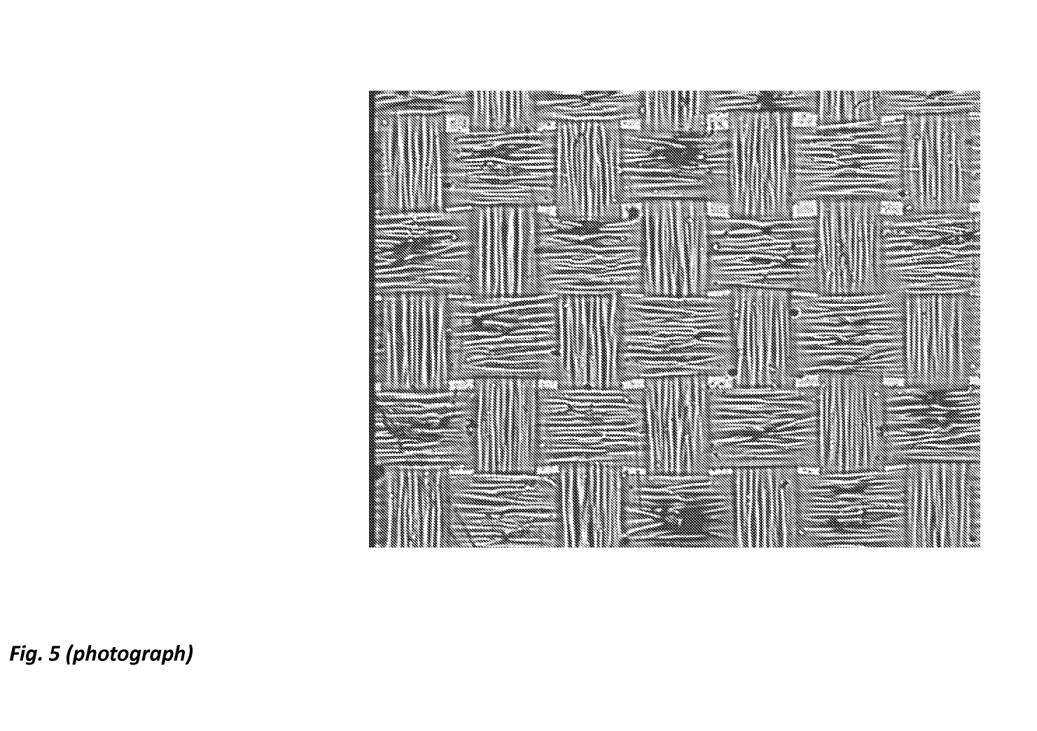

Woven aramid fiber substrates are made up of fiber bundles woven into a cloth with a precise 90° angle between bundles. This orientation provides the advantage of balancing in-plane CTE in both the X and Y directions and also provides superior mechanical strength. However, woven aramid may have several significant limitations in backplane-attached solar cell applications, including: relatively high material cost, potential future supply limitations (material is classified as a strategic material by the US government and can be placed on allocation), inconsistent laser hole drilling due to varying fiber densities through the weave, and high resin volume requirements to fill gaps and voids between the fiber bundles. FIG. 5 is a photograph of woven aramid fiber substrate at twenty times magnification.

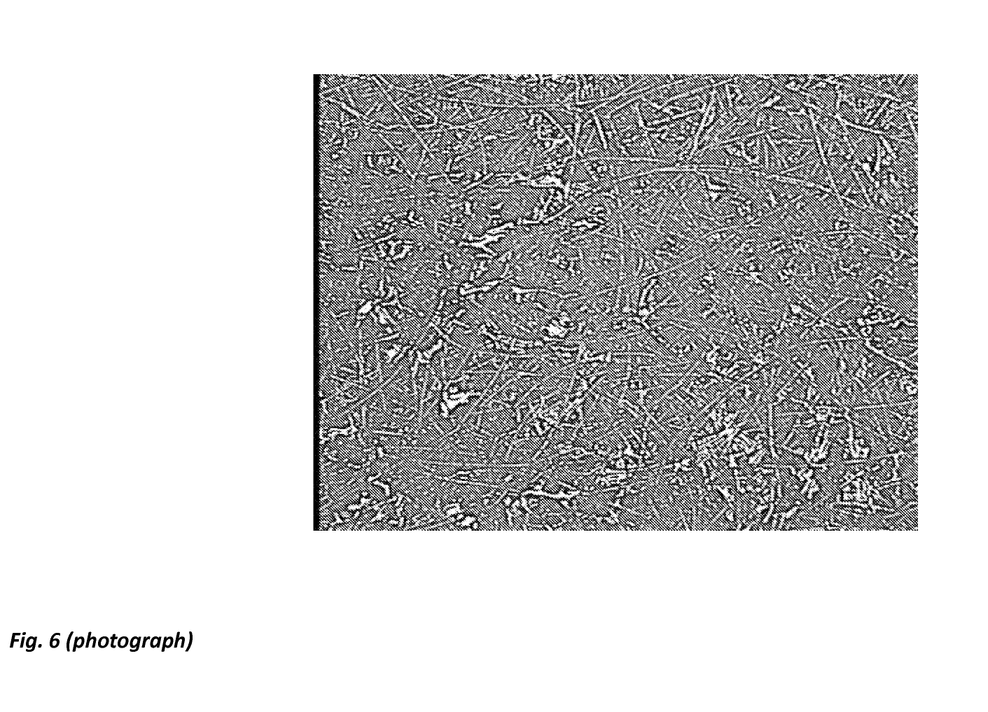

Non-woven aramid fiber substrates are made up of shorter fibers pressed into a paper like material with random fiber orientations in the X-Y plane. FIG. 6 is a photograph of non-woven aramid fiber substrate at twenty times magnification. Non-woven aramid fiber also exhibits a negative CTE in the X and Y directions but due to the random orientation of the fibers the amount of shrinkage is somewhat less than that of the woven material. The mechanical strength may be less than that of woven material but is sufficiently high for backplane-attached solar cell such as the embodiments provided herein. All the above-mentioned limitations noted for woven aramid material may be resolved when using a non-woven configuration. However, limitations unique to non-woven material include: a maximum sheet thickness limited to 6 mils, and tighter process uniformity requirements during prepreg manufacturing. Importantly, these limitations may have zero or minimal impact for solar cell backplane applications provided herein as thinner backplanes (for example having a thickness in the range of approximately 2 to 6 mils or about 50 microns to 150 microns are often preferred.

Further, extensive experimentation with prepreg made with non-woven aramid fiber supports that when paired with a compatible resin material, a direct CTE match with silicon may be achieved. Completed back contact silicon solar cells using backplane comprising non-woven aramid fiber and blended resin prepreg have been shown to meet solar cell product reliability requirements and the use of non-woven aramid fiber substrates is considered the primary fiber prepreg option for mass-scale manufacturing and commercialization of backplane-attached high-efficiency solar cells.

In yet another embodiment, carbon fiber may be employed. Carbon fiber substrates have broad application in aerospace and top end consumer products where high strength, high stiffness, high temperature tolerance and low weight are requirements although carbon fiber substrates are not typically used in the PCB industry. Carbon fiber substrates are only available in a woven configuration and are very expensive and may be cost prohibitive for cost-effective solar cell applications. Like aramid, carbon fiber has a very low CTE (typically in the range 1-2 ppm/° C.) and when paired with a compatible resin system may provide low CTE laminations with a CTE comparable to that of semiconductor absorber such as silicon. However, achieving an exact CTE match to silicon may be impossible due to the amount of resin volume required to fill gaps and voids in the woven carbon fiber substrate. An additional consideration with carbon fiber is electrical conductivity or lack of complete electrical insulation—in other words, electrical conductivity of carbon fiber is not high but may be a limiting factor in the maximum efficiency that could be achieved in backplane-laminated solar cell design.

Due to the limitations noted, in some instances carbon fiber backplane substrates are not considered a good fit for certain low-cost, high-efficiency solar cells—particularly from a cost perspective. However, carbon fiber backplane material is useful and applicable in backplane-attached solar cells where ultrathin (for instance, with thickness in the range of about 20 to 100 microns) backplanes with very high stiffness is desired.

In yet another embodiment, glass fiber substrates may be employed. Glass fiber substrates are the most commonly used material for prepreg in the PCB industry. Glass fiber offers an attractive cost competitive solution for most applications and may be combined with many resin systems. However, limitations of glass fiber prepreg in high-efficiency backplane-attached solar cell applications include: relatively high CTE (particularly with respect to silicon) in the range of about 5-7 ppm/° C., and difficulty with laser hole drilling uniformity (if required). These limitations may make glass fiber substrates less desirable for application as backplane in high-efficiency solar cell structure dependent on additional considerations. However, in one embodiment prepreg made with glass fiber may be utilized as a solar cell backplane if an additional layer of a different material is sandwiched between the silicon and glass fiber prepreg to decouple the relative CTE mismatch effects.

As described previously, prepreg is a fiber substrate which is saturated with a resin system that has been partially “cured” during the coating operation. In practice, the fabric substrate is coated with resin on a coater. Specifically, material is pulled through a pan filled with a solution of resin in solvent and then through a sequence of “metering bars” to accurately control the amount of resin deposited on the fabric. The resin saturated fabric is then pulled through a series of temperature-controlled oven zones in which solvent is removed and the resin is caused to partially react (or “B-Stage”).

As disclosed herein, CTE-matched with silicon (or nearly CTE-matched with silicon) prepreg may act as an ideal material for use as backplane to support thin crystalline semiconductor solar cells such as back-contact/back-junction solar cells using thin crystalline silicon absorber layers. Additionally, CTE-matched with silicon prepreg allows for mechanically-reinforced flexible solar cells with thin silicon semiconductor layers and formation of two-level metallization in a back-contact solar cell interconnection design. Because prepreg is only partially cured, it may be permanently laminated directly to the backside of the back-contact solar cells and fully cured in place (e.g., in a vacuum thermal laminator). Thus, prepreg resin forms a permanent bond to the solar cell backside surface (which comprises patterned Metal-1 or M1 contact metallization as well as uncovered portions of the solar cell substrate) and eliminates the need for additional adhesive leading to lower cost and improved reliability. As the maximum prepreg curing temperature is well below 250° C., solar cell wafers are unaffected by temperatures reached during prepreg curing. And although lamination pressure may be used to “flow” the resin during lamination curing, proper lamination fixture design mitigates risk of wafer cracking due to pressure.

Several critical control parameters during prepreg manufacturing which subsequently impact the backplane lamination quality should be considered. The most critical guideline is achieving a very specific ratio between the amounts of resin and fiber, referred to as Resin Content (RC) and which is typically described as a percentage. The achievable range of RC values in the prepreg is determined by several factors; type of resin, type of fiber substrate, minimizing defects for “dry fibers” on the low RC side and minimizing defects for bubbles/ripples on the high RC side. Backplane-attached crystalline silicon solar cells using thin (50 to 200 μm thickness) prepreg sheets with RC values ranging between about 20% and 65% have been fabricated. The RC should be relatively uniform across the width of the prepreg sheet (which is typically up to 50 inches) and length of prepreg roll (hundreds of yards) of the roll to achieve the consistency required for backplane-attached back-contact solar cell applications. Importantly, the prepreg backplanes for back-contact silicon solar cells disclosed are unique and significantly different from the traditional PCB industry prepreg. For example, the prepreg defect requirements for solar cell backplane applications are less stringent as compared to the PCB industry and result in lower manufacture costs and reduced prepreg material cost. However, in order to achieve the required CTE targets, RC uniformity must be maintained to well below ±5% and preferably better than ±1% tolerance in prepreg manufacturing.

The second critical factor in prepreg manufacturing for backplane supported solar cells is uniformity of the tension on the fiber substrate web as it is drawn through the coating machine during the prepreg roll manufacturing process. Uneven tension results in warp and weave distortion both detrimental to prepreg material consistency. For example, material that is manufactured with excessive warp will cause unacceptable axial bow in the laminated solar cell part. Material that has weave distortion will exhibit twist in the laminated part. Both bow and twist are detrimental to achieving parts that are planner. Therefore, for backplane applications in backplane-attached solar cells (including but not limited to the back-contact solar cells) the prepreg roll material must be manufactured with RC in the range of 20% to 65%, without uneven tension and without excessive warp and weave distortion.

The third critical factor related to prepreg roll manufacturing for backplane supported solar cells is preparation of the fiber substrate prior to processing through the coating line. Aramid material is susceptible to moisture absorption which is detrimental to the coating and B-stage curing processes. In practice, the substrate must be held under specific low humidity conditions prior to resin coating. This same issue applies to the prepreg sheet prior to lamination to the solar cell backside. Prepreg that is stored improperly could may subject to post-lamination delamination defects if the aramid fibers have absorbed environmental moisture prior to lamination. Therefore, for backplane attached solar cells (including but not limited to the back-contact solar cells) the prepreg roll should be manufactured under specific low humidity conditions prior to resin coating of the fiber substrate and the prepreg material must remain relatively moisture-free prior to the solar cell lamination process.

The ratio of resin to fiber (or resin content RC) is a critical factor in customization of prepreg for specific applications and particularly in the case of backplane-attached solar cells. In traditional PCB applications, RC values may be selected to balance: a) total resin volume for gap filling, and b) the CTE value of the final lamination. RC values of 50% to 75% are typical for prepregs used in PCB manufacturing. At these levels there is sufficient resin to fill all the gaps and voids in the board structure. Excess resin is pressed out of the board assembly during lamination and is later removed during board trimming. However, typical CTE values at these high RC values for an epoxy/woven aramid prepreg range between 7 and 9 ppm/° C. are too high for backplane-attached solar cell structures. For example, a backplane having a RC of 51% may result in solar cell bow outside of tolerance ranges.

For an epoxy/wover aramid prepreg a 5% decrease in RC equates to approximately a 1 ppm/° C. decrease in CTE. Thus to achieve a CTE value close to silicon would require an RC value of approximately 25% for an epoxy/woven aramid prepreg—a value which may be considered too low due to insufficient resin to fill gaps and voids on the metallized backside of the solar cell unless the backside topography is substantially planarized (for example with a spray coated or screen printed coating prior to the lamination process).

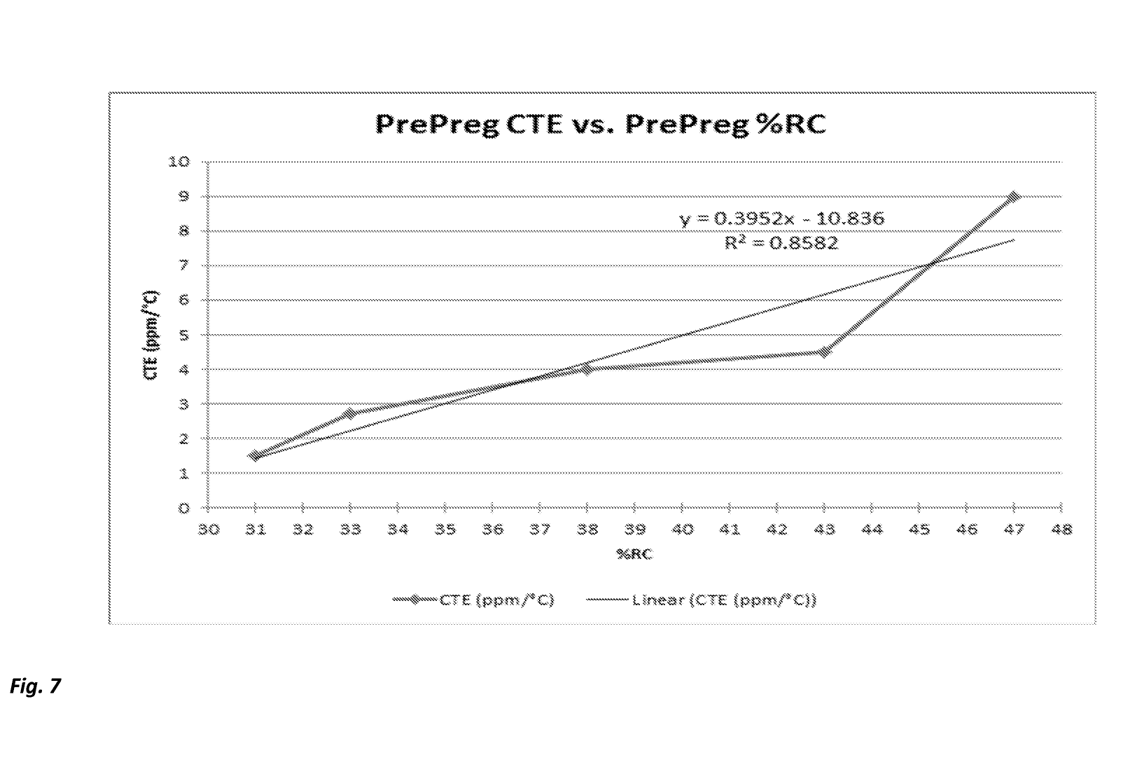

As noted previously, the backplane structures provided herein focus on a prepreg preferably using a “no flow” (or low flow, or low oozing) resin system coupled with a non-woven Aramid fiber substrate. With this design, a relatively close CTE match between cured prepreg and silicon has been achieved thus resulting in relatively flat laminated backplane-attached flexible solar cells. A target RC value in the narrower range of about 30% and 40% and more specifically around 33% has been established as a requirement to achieve a relative CTE match between prepreg and silicon. Experimental testing and manufacturing has confirmed that RC values on the order of about 32% and less may result in negative part warp while RC values on the order of 34% and higher may result in positive part warp. Thus an optimum range of RC values for aramid fiber prepreg material used as backplane for backplane-attached silicon solar cells in some instances is in the range of approximately 32% to 34% and there may be allowance for an RC value in a wider range of values (for example 30% to 45%) depending on post-lamination solar cell bow allowance. FIG. 7 is a graph showing data for Coefficient of Thermal Expansion or CTE vs. Resin Content for the aramid fiber prepreg material. Note cured 33% RC prepreg has a CTE essentially or closely matching the CTE of silicon.

And while the specific RC requirement to closely match CTE between cured prepreg and silicon has been determined, additional resin content considerations are applicable dependent on gap fill requirements. The backplane attached solar cells having aramid fiber prepreg backplane may be used when minimal gap filling on the solar cell backside is required and when significant gap filling on the solar cell backside is required.

For example, in the case where minimal gap filling is required—for instance, in the case of a relatively thin layer of patterned metallization layer (Metal-1 or M1) is formed on the backside of the solar cell prior to the lamination, and/or, when the backside surface is substantially planarized, for instance by application of a screen printed or spray coated dielectric layer for surface planarization—the total volume of resin within the prepreg is used to bond the total structure together and fill any voids within the prepreg fiber substrate. A target 33% RC for a prepreg with blended resin and non-woven aramid fiber substrate has been demonstrated to meet the design requirements with both 1 ply and 2 ply prepreg structures. The backplane-attached solar cells provided herein may use either single-ply or double-ply or multi-ply prepreg structure (in the case of multiple ply such as 2 ply backplane each ply may have a different RC value). Analyses of cross sections from completed backplane-laminated solar cells show a homogeneous, void-free, and relatively planar backplane-laminated solar cell structure. Further, the prepreg lamination process windows for temperature, pressure, and cure time are fairly wide allowing flexibility in selection of production lamination equipment for the solar cell backplane lamination.

In the case where significant gap filling is required—for instance, in the case of significant backside surface topography due to a thicker patterned M1—the total volume of resin has to be balanced between resin within the fiber substrate and resin “flowed” into gaps on the solar cell backside topography. Experimentation of solar cell backplane lamination with prepreg composed of blended resin and non-woven aramid fiber substrate has shown that a prepreg structure made up of 2 plys of prepreg, with each ply having a different RC values, may be used to make backplane-attached solar cells that meet the design requirements. Based on the embodiments of this invention, the prepreg ply that is in contact with the areas requiring gap filling must have sufficient resin volume to fill any gaps in the solar cell backside structure and fill any voids within the fiber substrate as well. RC values from about 45% to about 50% may be required for the gap filling ply, for example for lamination to a back-contact cell structure with screen-printed and high aspect ratio Ml contact metallization. In order achieve relative CTE matching between cured prepreg and silicon, the high RC ply must be co-laminated with a low RC ply so that the total laminated structure has a final RC of about 33% (or in the overall range of 31% to 35%). This results in the 2′ ply having RC values from about 16% to about 21%. This 2′ layer of prepreg must contain sufficient resin to both “wet” the fiber substrate to eliminate voids and encapsulate the individual aramid fibers and to make a reliable continuous resin to resin bond to the 1s^{t} ply. Analysis of cross sections from completed backplane-attached solar cells shows a homogeneous, void free solar cell structure has been achieved using this 2-ply backplane lamination configuration. However, the lamination process windows for temperature, pressure, and cure time are considerably narrower for this embodiment and there is reduced flexibility in selection of production lamination equipment for the application.

Alternatively, a single ply of fiber substrate may be manufactured to have an asymmetric or graded resin coating across the thickness of the prepreg side to side for significant gap filling applications. The prepreg side in contact with the cell structure should have sufficient resin (higher resin content or higher RC) to fill any gaps while the opposite prepreg side will have minimal resin (lower resin content or lower RC) sufficient only to ensure fibers are fully encapsulated. This asymmetric resin coating with graded RC across the prepreg thickness results in a material with an average (volume-averaged) RC of about 33% and requires the same relatively narrower processing windows as the 2 ply path detailed above.

Importantly, gap filling may also be achieved by pushing resin from a prepreg substrate into gaps during lamination by utilizing high pressure lamination thus resulting in a backplane having a 100% resin content portion flowed between the on-cell metallization and a second prepreg portion containing an aramid fiber and blended resin (e.g., resin with a thermoset such as a thermoplastic rubber). The second prepreg portion may have a resin content in the range of 28%—thus balancing the total resin content for the backplane, for example to a resin content of 39%. Thus the second prepreg portion acts as an expansion control layer working in combination with the semiconductor substrate, for example a silicon semiconductor substrate. This backplane structure is outlined in the backplane supported solar cell cross-sectional diagrams of FIGS. 2 and 4.

At the broadest level, the backplane used for backplane-laminated solar cells is a structural support for a thin silicon absorber layer of a backplane-attached solar cell. The electrical function of the cell is not dependent on a specific thickness of the backplane as long as the backplane meets specific dielectric or electrical insulation requirements. Thus, the selection of a target backplane thickness may be primarily driven by goals for solar cell mechanical robustness and backplane-attached product cost. The final prepreg backplane thickness for backplane attached solar cells may be in the range of about 2 mils (or approximately 50 microns) up to about 10 mils (or approximately 250 microns), and in some instances a preferred prepreg thickness is in the range of about 3 mils to 8 mils (or approximately 75 microns to 200 microns).

Flexible (or bendable) backplane-attached solar cells may be made with prepreg having a thickness totaling about 8 mils (or approximately 200 microns)—for example one prepreg ply having a thickness of 8 mils or two prepeg plys each at 4 mils thick—and with prepreg having a thickness totaling 4 mils (or approximately 100 microns)—for example 1 ply at 4 mils thickness.

Further, solar cell manufacturing process steps may be optimized for prepreg thickness. With reference to the 8 mil and 4 mil prepreg plys above, from a mechanical robustness standpoint solar cells having 8 mil thick backplanes are semi rigid and with proper handling protocols may be manually transferred step to step with minimal risk of cell damage. Solar cells having 4 mil thick backplanes are relatively flexible and limber and may require stringent handling protocols to prevent cell damage during processing, thus a 4 mil design may better suited to automated handling and transfer. Another consideration is material cost, to reduce material costs a thinner backplane may be desired. Thus with reference to the 8 mil and 4 mil prepreg plys above, the backplane design may use a 4 mil solution to minimize raw material costs.

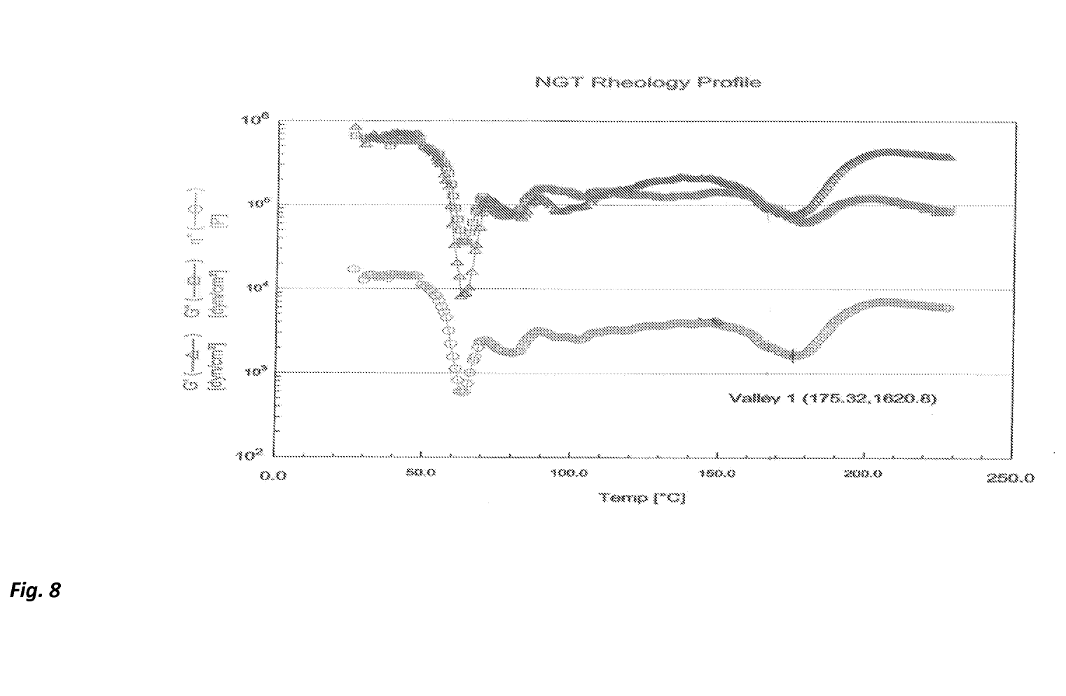

For backplane attachment, curing properties of the resin system are critical to determination of the optimal processing conditions for temperature ramp and lamination pressure. FIG. 8 is a rheology graph outlining the rheology profile for a blended resin system. Rheology curves describe the specific properties of a resin system as the material progresses from B-stage through resin melt through resin gelation and finally to full cure. Epoxy resin systems are well understood and specific process conditions to optimize gap filling, void elimination, and uniform lamination thickness by the solar cell lamination process may be optimized. Blended resin systems go through more complex curing cycles and the rheology curve is critical for lamination process optimization.

With reference to FIG. 8, the circle curve (n*circle) shows the viscosity change of the resin verses temperature. In this system a minimum viscosity is reached at 175° C. The square (G″ square) and triangle (G′ triangle) curves illustrate the Shear Storage Modulus (G′) and the Shear Loss module (G″). Typically the crossover of the G′ and G″ lines indicates the point where the resin system begins to gel and the viscosity increases. In the case of the certain blended resin systems, the crossover point may be poorly defined but the curve illustrates that gelling of the resin has begun at a temperature lower than the minimum viscosity point. Using this information, lamination processes have been developed utilizing fast heating ramp rates to quickly reach the minimum viscosity point so resin can be flowed into gaps and voids before the gelation process progresses far enough to prevent resin flow.

The glass transition temperature is the point where cured resin transitions from a hard, brittle state to a soft, rubber like state. This parameter is a critical consideration in the PCB industry but is less significant in backplane attached solar cells. When the Tg temperature is reached, the most dramatic change is that the CTE increases by 3× to 4× over the value below the Tg point. The CTE increase is not a significant consideration in the X-Y plane due the constraining effect of the fiber substrate but is a significant effect in the Z-axis. In traditional PCB applications, the increased Z-axis CTE has resulted in failures of electrical connections in plated through vias. The stress on the plating due to Z-axis expansion of the prepreg is sufficient to fracture connections.

However in backplane attached solar cells this failure mode may be avoided. For example, while there may be relatively high temperature steps (such as PECVD passivation deposition at temperature of up to about 300° C.) in the solar cell manufacturing flow after lamination, the maximum processing temperature post lamination (and thus also post M2 metallization) is limited to less than about 300° C. Further, the completed backplane-attached solar cell may be exposed to a temperature close to the Tg point during lamination into a module assembly. Module lamination may expose cells to a heating up to approximately 130° C., for example to cure the thermoset resin in the module structure. But this relatively low heating event is unlikely to result in a failure of the metallization structures (including the M2 structure).

The use of additives in resin systems is common in the PCB industry. For example, typical additives include: fire retardants, adhesion promoters, cross linking inhibitors/accelerants, pigments, fillers to achieve specific CTE, electrical or thermal conductivity requirements, UV stabilizers and others. Resin systems are modified with additives for specific applications. Solar cell backplane requirements are uniquely different from traditional prepreg applications which may result additive adjustments.

For example, the use of non-woven Aramid fiber substrates prevents the use of fillers within the resin system. The substrate fiber density is high enough that it acts as a filter and prevents uniform dispersion of fillers into the prepreg structure. This characteristic of the fiber substrate limits the options for using additives to match CTE between the backplane and solar cell substrate (e.g., silicon) and also limits the ability to modify the thermal conductivity of the backplane. Fillers are not required in the backplane attached solar cells provided herein.

Second, as a final product solar cells are fully encapsulated in a module encapsulant (e.g., EVA, polyolefin, or another suitable encapsulant) that hermetically seals in the solar cell parts and also acts to block a majority of unwanted UV light. This encapsulant eliminates the need to include flame retardants and UV stabilizers in the prepreg. No retardants or stabilizers are used in the backplane attached solar cells provided herein.

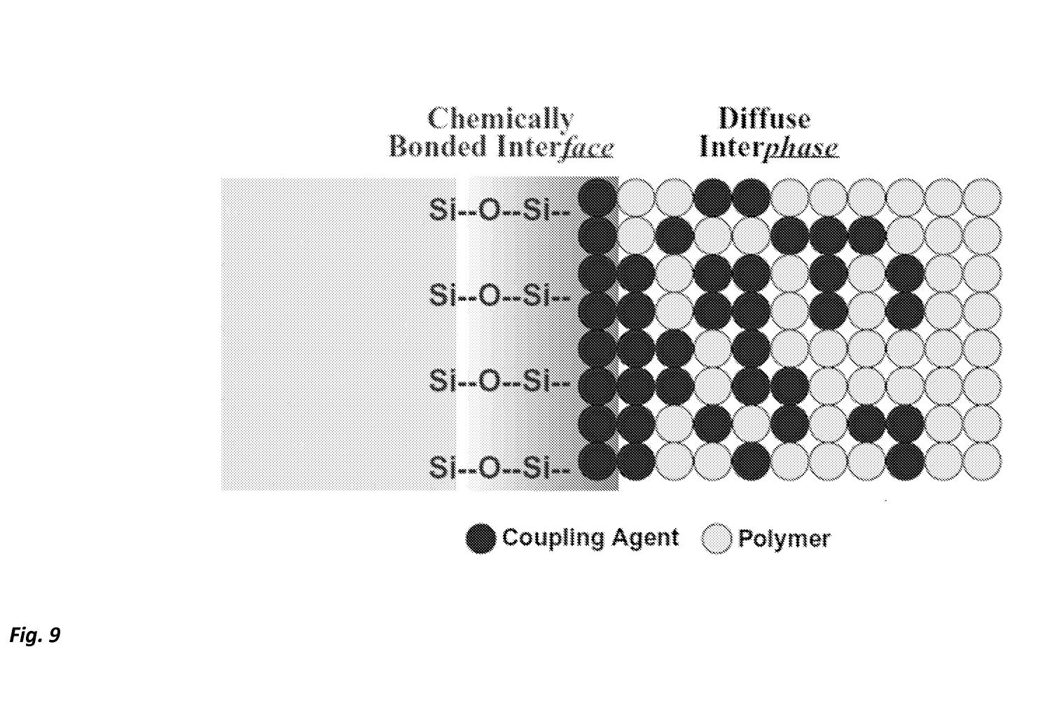

Third, the adhesive properties of resins are highly dependent on the polarity of the resin and its ability to form molecular level bonds with other materials. Epoxy type resins are highly polar and form strong bonds. Backplanes utilizing epoxy resin systems have been very successful in several generations of the backplane-attached solar cell designs. When using blended resin systems, issues arose relating to adhesion to silicon and silicon oxide. As a result, optionally a silane based adhesion promoter may added to the resin system to resolve the adhesion problem dependent on additional considerations and structure design. Silane coupling agents contain inorganic reactive groups on silicon and bond well with most inorganic substrates, particulalry if the substrate contains silicon or aluminum as in the case of the backside surface of the back-contact solar cells embodiments provided. FIG. 9 is a diagram illustrating coupling of the silane to silicon oxide and diffusion of the additive within the resin. Adhesion issues were resolved when silane was used. Thus, in one backplane attached solar cell embodiment silane adhesion promoter is added to prepreg in contact with silicon oxide on the backside surface of the metallized solar cell.

Fourth, an end product solar cell may require certain aesthetics. Pigment may added to the resin system to mute the natural color of the aramid fiber substrate. For example, requirements for the pigment include: transparency in the Infrared (IR) spectrum, compatibility with CO2 laser cutting and via drilling, and compatibility with all chemicals used in the solar cell manufacturing process.

Thus, although blended resin system may be modified with the addition of a silane adhesion promoter and a pigment, no other additions are required to meet the functional requirements of backplane-attached solar cell structures and applications embodiments disclosed herein.

Resin may be used as a stand-alone component for filling the gaps in the backside metal structure of a backplane-attached solar cell. This strategy is most useful when the height of the M l or contact metallization metal structure on the backside is quite thick (for instance between about 20 microns and 50 microns) resulting in high aspect ratio back contact solar cell surface topography and it is undesirable to use the resin in the prepreg for gap filler. In practice, a wide range of materials may be useful as effective gap fillers—for example, various types of UV curable resins/adhesives and with very low modulus thermoset resins that can be applied using screen printing or stencil techniques directly to the solar cell. CTE matching of the gap filling material is not a major consideration because a sheet of low CTE prepreg is also used as the primary structural support for the backplane-attached solar cell. The prepreg CTE should be relatively matched to silicon so the two layers (the prepreg and the silicon solar cell substrate) act as a constraining layer for the gap filling material—in other words the prepreg sheet and the solar cell substrate act as expansion control layers sandwiching the gap filling material and on-cell metallization layers. Even considering cost, the use of a gap filler and single sheet of prepreg is also a viable option for commercialization.

Importantly, in a primary embodiment the same resin system used in the prepreg may be used as a gap filler. This requires lamination process optimization to push resin from the prepreg for flow within the on-cell metallization. This backplane structure is outlined in the backplane supported solar cell cross-sectional diagrams of FIGS. 2 and 4.

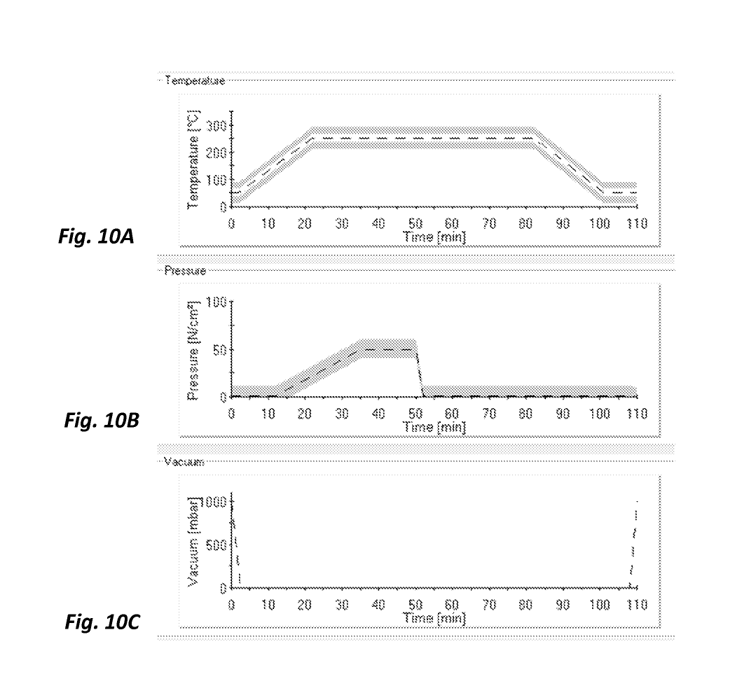

A lamination process may be used to bond the prepreg to the solar cell. Lamination uses heat and pressure to complete curing of resin in the prepreg sheet which bonds it with the cell. FIGS. 10A, 10B, and 10C are graphs showing a lamination process profile of a blended resin system. FIG. 10A is a graph showing the temperature profile, FIG. 10B is a graph showing the pressure profile (note the pressure drop during the lamination process), and FIG. 10C is a graph showing the vacuum conditions. The following describe primary considerations for selection of process conditions to ensure acceptable lamination results.

The maximum temperature used for curing prepreg is dependent on three primary factors: reaching targeted cure levels of the resin, establishing the thermal history of the prepreg structure, and achieving efficient process cycle times.

For either the epoxy or blended resin system a minimum curing temperature (e.g., most manufacturer recommended minimum curing temperatures) is often in the range of 180° C. to 190° C. for 90 minutes. For epoxy resin, curing temperatures up to a maximum of approximately 220° C. may be used without damage to the prepreg. A blended resin system has a greater tolerance for high temperature and lamination may be performed up to 275° C. At the higher temperature, lamination should be performed in a vacuum or inert gas environment to prevent surface darkening of the prepreg resin due to oxidization.

Establishing a “thermal history” in the cured prepreg is an important consideration backplane attached solar cells. During resin curing, the stress conditions within the prepreg structure are set based on the thermal profile and on the maximum temperature reached. The internal stresses will be different for parts laminated at 200° C. verses those laminated at 250° C. Because solar cells will be exposed to additional high temperature environments after lamination it may be necessary to expose the parts to a higher target temperature during lamination. A general rule of thumb is to laminate at a temperature 25° C. higher than the maximum temperature the parts will be exposed to post lamination.

A specific advantage of laminating at higher temperatures is that the resin will cure more completely. The amount of cross linking in resin is a function of both time and temperature. By processing at high lamination temperatures there will be less additional resin cure post lamination when the parts are exposed to elevated temperatures during manufacturing.

Current lamination process cycle times may be set at 110 to 120 minutes from lamination press load to unload. This cycle duration is designed to fully cure the resin at a target temperature of 250° C. (110 minute cycle) to 275° C. (120 minute cycle). Cycle time optimization highly benefits from on-going processes engineering.

Heat up and cool down ramp rates are a significant variable in the PCB industry. Typically heat up rates are tailored to a specific resin system to balance the flow of the melted resin vs. the initiation of resin gel. The cool down rate is used to manage the residual stress built up in multi-layer PCB due to the CTE mismatch between the layers. Typical recommendations are heating ramps of 3° C. to 7° C./min and cooling ramps of 3° C. to 5° C./min. In backplane attached solar cells using blended resins, an aggressive heat up ramp may be desirable to reach maximum resin flow before gelling occurs. Excellent results have been obtained with ramp rates as high as 10° C./min. Relating to cool down, with the CTE matched between the prepreg and silicon there is less concern with build-up of residual stress during cooling. As a result, in some instances an aggressive cooling ramp of 8° C./min (limited by the process equipment) may be used.

Pressure applied during lamination serves to distribute the resin within the structure for gap filling and void reduction. Operating at very low pressures results in a finished structure with poor adhesion between layers and voids within the prepreg structure. Operating at very high pressures results in a uniform structure but can potentially crush/distort the fiber substrate, cause residual stress to build up in the finished structure, and cause wafer cracking In backplane attached solar cells, three critical parameters should be balanced when determining the pressure used for lamination: minimum pressure, maximum pressure and how pressure is profiled during lamination.

The first critical minimum pressure parameter is elimination of gaps and voids. Gaps and voids degrade the structural integrity of the assembly and have been shown to cause yield loss in the manufacturing process. Determining the required minimum pressure requires knowing the pressure required to close voids within the prepreg material and knowing the pressure required to flow molten resin into the gaps in the lamination structure.

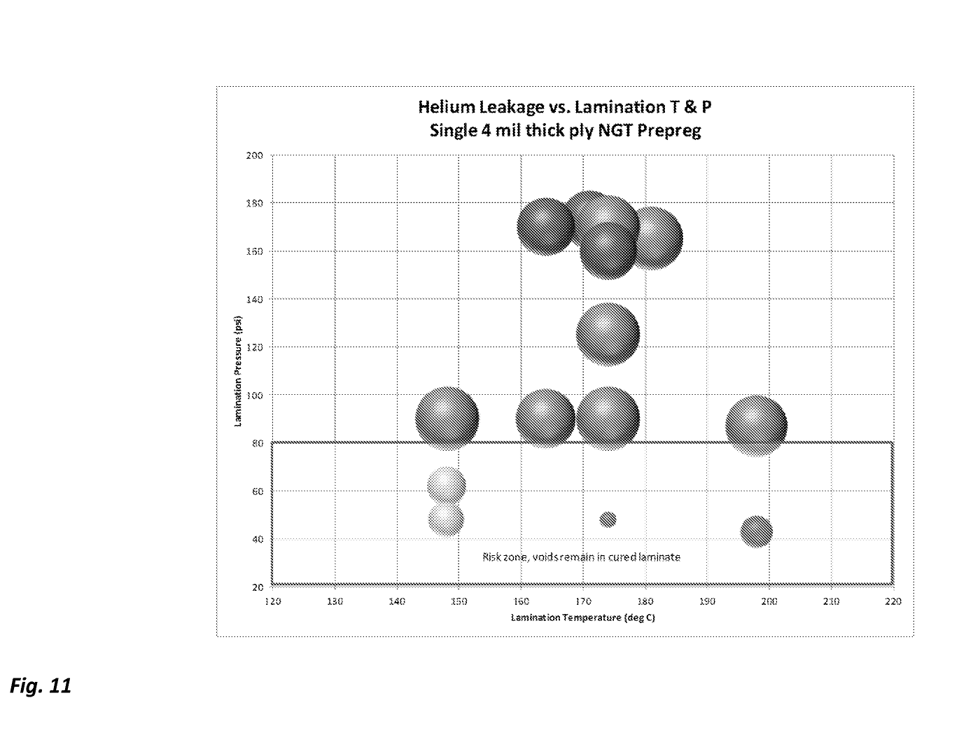

A helium leak test methodology has been developed to find the minimum pressure to ensure voids within the prepreg are closed. In practice, single ply, large area samples of prepreg material (1.5× the surface area of the solar cell) are cured under specific pressure and temperature conditions. The cured samples are then analyzed for voids using pressurized helium leak testing. When voids are present, helium will leak through the cured sheet and be detected. The amount of flow determines the severity of the voids. The acceptance criteria is zero voids. FIG. 11 is a graph illustrating the outcome of a series of tests run on samples with the blended resin system. This specific investigation showed that a minimum lamination pressure of 80 psi was required to ensure the cured laminate was void free.

A second critical minimum pressure parameter is resin flow within the cell structure. Back-contact solar cell designs use metal structures (e.g., M1) on the backside surface of a passivated silicon cell to make electrical contact and collect current. These metal structures (e.g., interdigitated Ml metallization fingers) range in height from about 1 micron to about 50 microns above the passivated silicon backside surface. Because the prepreg contacts only the tops of the metal structures it is suspended away from the cell surface at the start of lamination. Pressure applied during the process must cause resin to flow into the gaps and ensure a void free final structure. For example, a pressure of about 100 psi may be required to gap fill with metal structures in the sub 10 micron height range and a pressure of about 200 psi may be required with thicker Ml metal structures (e.g., in the 50 micron height range).

The maximum pressure limit may be determined by reaching the damage threshold of various parts of the solar cell structure. For example, damage can occur to: a) the thin semiconductor (e.g., silicon) layer that is bonded to the backplane, b) a wafer carrier (e.g., silicon wafer or silicon template for an epitaxially grown thin silicon semiconductor layer) that is used to support the thin layer prior to backplane lamination, or c) the metal structures on the solar cell. In some cases, damage to the metal structures may be the gating or determining factor. For example, back contact solar cell metal structures (e.g., on-cell base and emitter metallization Ml) can tolerate maximum lamination pressures of approximately 300 psi before a delamination failure mode occurs. In contrast, damage thresholds for exemplary wafer carriers and the thin semiconductor (e.g., a silicon layer epitaxially grown on a silicon template) may be greater than 800 psi with zero or minimal issues.

A strong link between how pressure is applied during the duration of the lamination cycle and the amount of warpage in the finished part has been determined. When identical parts are processed, a process where pressure is applied and held constant throughout the lamination cycle will result in part warpage. However, a process where pressure is applied and removed during the lamination cycle will result in parts with no warpage. Thus, use of a process with varying pressure during lamination may be a requirement to achieve the design goals of the finished solar cells—as shown by the during lamination pressure drop outlined in FIG. 10B.

Vacuum during lamination is an optional lamination parameter in the PCB industry. Millions of PCB assemblies are made daily with lamination processes that use only lamination pressure to ensure a void free structure. In general, non-vacuum processes are used when there is a sufficient quantity of resin in the prepreg to easily flow and disperse any trapped air out of the assembly through resin flow.

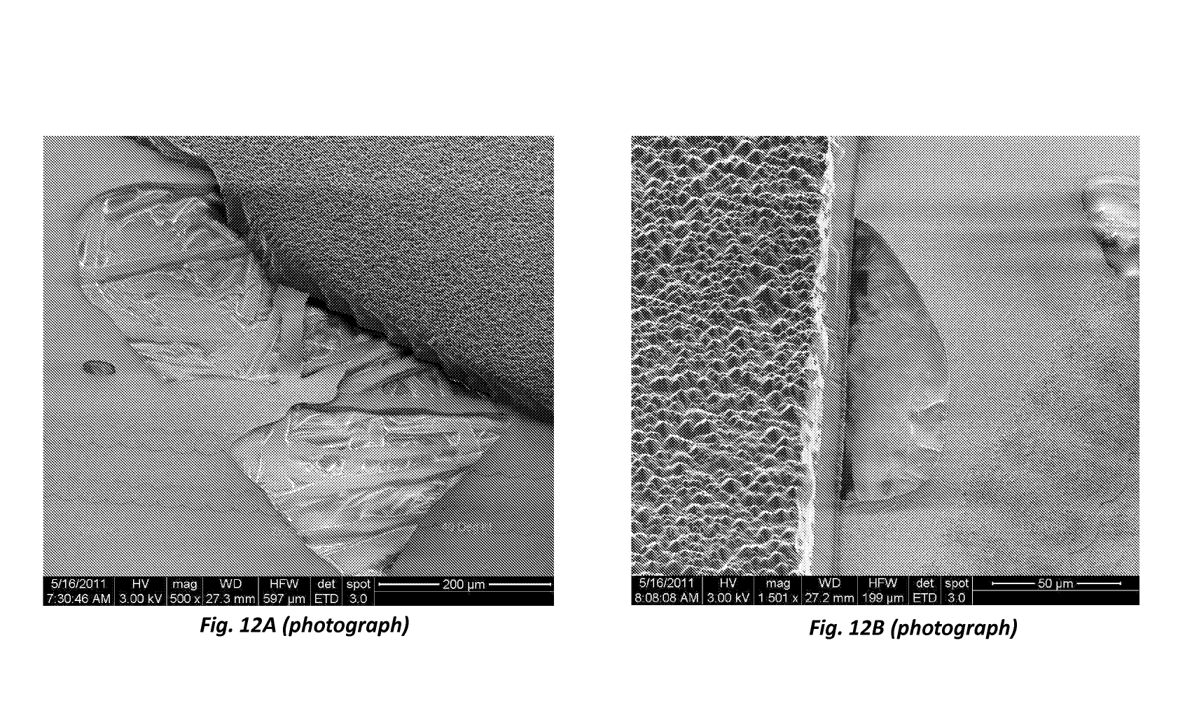

In backplane attached solar cells using a “no flow” blended resin, use of vacuum during lamination may be a requirement. In other words, there may be insufficient resin flow to “push” bubbles out of the assembly so excess air must be evacuated using vacuum. FIGS. 12A and 12B are SEM photographs highlighting voids in the solar cell structure occurring during a non-vacuumed lamination and showing parts where silicon delaminated from the cured resin due to trapped bubbles. A manufacturing step after lamination where the parts are placed into high vacuum at elevated temperatures may be used to pop any air filled bubbles in the lamination. The parts shown in FIGS. 12A and 12B were intentionally manufactured without using vacuum and air was trapped between the silicon and prepreg layers during lamination. For backplane lamination of prepreg to a solar cell, lamination equipment should have vacuum capability and the parts held under vacuum for the entire duration of the lamination cycle.

Total cure time is a critical parameter in establishing the mechanical properties of the cured lamination. Shorter cure times run the risk of not completely curing the resin which then result in poor mechanical properties in the finished part and require additional resin curing in later solar cell manufacturing steps. Longer cure times are inefficient and are only required if the curing temperature is at the minimum (e.g., the minimum recommended curing temperature). For backplane attached solar cells, the selection of resin and maximum curing temperature results in an efficient cure duration of 60 minutes—a cure time significantly faster than typical lamination but has been shown to provide a fully cured assembly meeting all mechanical requirements.

In traditional PCB manufacturing, the platens used to hold parts during lamination cycles are generally made from stainless steel. Advantages of stainless steel include, for example: low CTE, excellent heat transfer properties, and stainless steel may be machined to high flatness tolerances. In addition to the platens, various types of spacers, release sheets and conformal pressure transfer layers are added into the lay-up to form a “book” of parts. The book is placed into the lamination press and all parts in the book are processed at the same time.

The prepreg substrate may be laminated to a back contact solar cell using processing very similar to that from the PCB industry. One notable exception being that the platens may be made from either aluminum or stainless steel. Extensive experimentation with aluminum platens has shown that they provide excellent heat transfer properties and are lighter in weight than stainless steel. The higher CTE value of aluminum is not detrimental to meeting the design requirements for a finished solar cell product as long as there are decoupling layers within the book. The stack-up of materials to form the book is critical to ensure decoupling of the various parts to account for CTE mismatches.

The selection of release sheet and conformal pressure transfer materials may be adjusted to account for the significantly higher temperatures used during lamination. Standard materials may be sourced from the PCB industry for these high temperature layers to help minimize manufacturing costs.

Solar cells made with crystalline silicon are fragile and may be easily damaged due to mishandling. However, the backplane designs provided are robust and may be flexible—thus allowing completed solar cells using very thin silicon layers to be easily handled and transported with minimal to zero damage risk. This attribute affords the ability to use simple cassette to cassette transfer tools and simple machine automation tools in manufacturing. Manufacturing yield loss due to part breakage are minimal after the backplane is laminated to the silicon layer of the solar cell. As the thickness of the backplane is reduced, the solar cells become very flexible. Handling practices may be adjusted to minimize the risk of folding or creasing the parts and handling tools are setup to ensure they have a soft touch.

The prepreg backplane supported solar cells structures disclosed provide excellent in process manufacturing reliability as well as reliability and durability within solar cell end use operational limits for temperature and humidity. These reliability performance results further support the viability of solar cell design (backplane materials and lamination processes) for use in high-efficiency solar cells. For example, thermal cycling is used to determine the ability of the module to withstand thermal mismatch, fatigue and other stresses caused by repeated changes of temperature. Importantly, esting according to specific requirements (exemplary thermal cycle, humidity, and humidity freeze tests administered per International Electrotechnical Commission requirements at IEC standard 61215, rev 2) have shown prepreg backplane supported solar cells have substantially exceed certification requirements. For example, prepreg backplane supported solar cells have survived 400 thermal cycles of standards testing requiring module temperatures of −40° C. for a minimum of dwell time of ten minutes and 85° C. for a minimum dwell time of ten minutes (with a maximum 100° C./hour temperature ramp. change). Humidity testing is used to determine the ability of a module to withstand the effects of long-term penetration of humidity. Prepreg backplane supported solar cells survived a soaking test through 1,300 hours where modules are held for hours at a temperature of 85° C.±2° C. and relative humidity of 85%±5 using a sample configuration with worst case module laminations made without edge seals and using a backsheet material known to allow moisture penetration in long-term high humidity conditions. Humidity freeze test is used to determine the ability of the module to withstand the effects of high temperature and humidity followed by sub-zero temperatures. Prepreg backplane supported solar cells have survived through 38 cycles of this IEC certification test and samples have shown no issues through approximately 4× the certification requirements.

Understanding historical failure modes from the PCB industry may be useful in estimating the potential failures modes that may occur for prepreg backplane supported solar cells designs. Types of failures that might be experienced by a solar cell may be determined through a measurable loss in performance. With PCBs a single lost connection can cause the entire assembly to fail while in solar cells a lost connection will degrade the power output. Reliability test pass/fail results are based on the amount of power loss seen over the duration of testing. In both PCB and solar cell applications the loss of an electrical connection is due to joint failures which may be caused by: CTE mismatches, fatigue fracture due to thermal or mechanical cycling, or delamination due to moisture ingress. Each of these failure modes has been investigated and discounted as a concern in the course of performing reliability testing.

To address CTE mismatches the innovative methodology provided establishes a CTE match between the silicon solar cell and the prepreg backplane. This matching of CTEs prevents stress to the electrical connections with temperature changes and eliminates this traditional PCB failure mode.

Failures caused by thermal and mechanical cycling are addressed through the combination of very low CTE and selection of resin with a Tg point above the operational range of the solar cell. These design characteristics ensure electrical connections are never in tension or shear. For example, the high CTE of copper plating (approximately 17 ppm/° C.) and other metals ensures that it is constrained by the low CTE of the prepreg thus keeping the copper under compression as temperatures rise. Additionally, the inherent flexibility of the prepreg backplane allows it to flex during mechanical loading to prevent build up of interlayer shear stress which may cause failures. For added margin, several thousand electrical contact points to the solar cell (e.g., the M2 to M1 electrical connection) may be made through vias in the backplane. Aramid fiber substrate have also been proven in years of service in harsh environments to provide significant margin at prevention of micro-crack formation around via locations. A high via count provides a level of redundancy and minimizes the effect if a small number of connections degrade of the 25 year field life expectancy of a solar cell.

To address moisture ingress, a blended resin system may reduce the moisture absorption of the prepreg by a factor of thre over epoxy resin systems. The result is a product that is less sensitive to high humidity environments, adding margin to the product in field installations. The two high humidity tests performed during reliability demonstration strongly indicate humidity is not a concern.

Thus, traditional failures modes from the PCB industry may be addressed through prepreg material selection and electrical contact redundancy in the solar cell.

In operation, the unique solutions provided herein for support of thin silicon based solar cells using a highly capable, low cost prepreg backplane is industry altering. The prepreg backplane eliminates the barrier to handling and processing very thin silicon and open the path to reaching very competitive product costs. Additionally, the potential applications for this technology are broad reaching. Key backplane attributes of: low cost, flexibility, simple manufacturing processes and robust reliability may be used in a range of solar cell architectures and the prepreg may be easily modified for compatibility with many different solar cell raw materials. The ability for flexible cells opens many potential applications outside of traditional module designs including consumer electronics, Building Integrated PV (BIPV) products, and automotive applications.

The M1 and M2 metallization layers described herein are separated by the dielectric prepreg layer and connected by conductive vias through the prepreg—alternatively the M1 and M2 metallization layers may be electrically connected by conductive posts. FIGS. 3 and 4 are cross-sectional diagrams of a back contact solar cell having M1 and M2 metallization. The metal layer close to solar cell (M1) may be deposited using physical methods (PVD, paste printing) or using chemical techniques (CVD). The prepreg layer is then laminated with binding resin. Vias may be drilled subsequent to backplane lamination/attachment using mechanical, chemical, or laser drilling techniques. The vias may then cleaned using plasma sputtering, reactive species plasma or wet chemistry. In one M2 fabrication embodiment, the seed layer for top level metal layer (M2) is deposited using PVD, ink jet or screen printing and subsequently a thick metal is plated onto the seed layer to reduce the line resistance and resistance in the vias. The front-side of the cell (for example having an anti-reflective coating layer ARC layer) should be protected from the plating and etching bath. In one embodiment, a single-sided fixture is attached to the cell front-side during the wet chemistry steps during plating and subsequent metal etch patterning to define the M2 lines.

The dual-level metallization back contact solar cells described herein may be formed on a thin film silicon substrate formed using an epitaxial growth process or a mono-crystalline, quasi mono-crystalline, or multi-crystalline silicon CZ wafer. Tables 1 and 2 below present two process flow embodiments and corresponding processing steps for the formation of a thin crystalline (having a thickness in the range of approximately 5 to 100 um) back-contact back junctionsolar cell with dual-level metallization from an epitaxially grown substrate (Table 1 beginning at porous layer formation in a porous silicon/epitaxial substrate deposition/release process) and from a CZ wafer (Table 2).

TABLE 1
Epitaxial based thin mono-crystalline (5 um to 100 um) back-contact
back-junction solar cell with dual level metallization process flow.

| | | |
|---|---|---|
| 1. | Porous Silicon | Anodic Etch |
| 2. | Silicon Epitaxy | Epi Tool |
| 3. | BSG Deposition | APCVD |
| 4. | BSG Opening | Laser |
| 5. | PSG Deposition | APCVD |
| 6. | Anneal/Back passiv. | Furnace |
| 7. | Open Contact | Laser |
| 8. | Al Paste Print, Dry | Screen Print |
| 9. | Anneal | Laser |
| 10. | Backplane, Release | Laminator, MR |
| 11. | Texturization | Wet Etch |
| 12. | Front Passivation | PECVD |
| 13. | Backplane Holes | CO2 Laser |
| 14. | Metallization | Plating |

TABLE 2
Harmonized process flow for CZ wafer based thin mono-crystalline,
quasi mono-crystalline, or multi-crystalline back-contact back-
junction solar cell with dual level metallization.

| | | |
|---|---|---|
| 1. | BSG Deposition | APCVD |
| 2. | BSG Opening | Laser |
| 3. | PSG Deposition | APCVD |
| 4. | Anneal/Back passiv. | Furnace |
| 5. | Open Contact | Laser |
| 6. | Al Paste Print, Dry | Screen Print |
| 7. | Anneal | Laser |
| 8. | Backplane | Laminator |
| 9. | Si Cut | Laser |
| 10. | Texturization | Wet Etch |
| 11. | Front Passivation | PECVD |
| 12. | Backplane Holes | CO2 Laser |
| 13. | Metallization | PVD |
| 14. | Metal pattern | Laser |

A more detailed epitaxial based back contact solar cell process flow is provided below. Numerous aspects of this process flow, and particularly those relating to metallization, are applicable to non-epitaxial based back contact solar cells. Starting with a reusable silicon template, for example made of a p-type monocrystalline silicon wafer, a thin sacrificial layer of porous silicon is formed (for example by an electrochemical etch process through a surface modification process in an HF/IPA wet chemistry in the presence of an electrical current). The starting material or reusable template may be a single crystalline silicon wafer, for example formed using crystal growth methods such as FZ, CZ, MCZ (Magnetic stabilized CZ), and may further comprise epitaxial layers grown over such silicon wafers. The semiconductor doping type may be either p or n and the wafer shape, while most commonly square shaped, may be any geometric or non-geometric shape such as quasi-square or round.

Upon formation of the sacrificial porous silicon layer, which serves both as a high-quality epitaxial seed layer as well as a subsequent separation/lift-off layer, a thin layer (for example a layer thickness in the range of a few microns up to about 70 microns, or a thickness less than approximately 50 microns) of in-situ-doped monocrystalline silicon is formed, also called epitaxial growth. The in-situ-doped monocrystalline silicon layer may be formed, for example, by atmospheric-pressure epitaxy using a chemical-vapor deposition or CVD process in ambient comprising a silicon gas such as trichlorosilane or TCS and hydrogen.

Prior to backplane lamination, the solar cell base and emitter contact metallization pattern is formed directly on the cell backside, for instance using a thin layer of screen printed or sputtered (PVD) or evaporated aluminum (or aluminum silicon alloy or Al/NiV/Sn stack) material layer. This first layer of metallization (herein referred to as Ml) defines the solar cell contact metallization pattern, for example fine-pitch interdigitated back-contact (IBC) conductor fingers defining the base and emitter regions of the IBC cell. The Ml layer extracts the solar cell current and voltage and transfers the solar cell electrical power to the second level/layer of higher-conductivity solar cell metallization (herein referred to as M2) formed after M1.

After completion of a majority of solar cell processing steps, a very-low-cost backplane layer may be bonded to the thin epi layer for permanent cell support and reinforcement as well as to support the high-conductivity cell metallization of the solar cell. The prepreg backplane material may be thin (for instance, a thickness in the range of approximately 50 to 250 microns and in some instances in the range of 50 to 150 microns), flexible, and electrically insulating. The mostly-processed back-contact, back-junction backplane-reinforced large-area (for instance, a solar cell area of at least 125 mm×125 mm, 156 mm×156 mm, or larger) solar cell is then separated and lifted off from the template along the mechanically-weakened sacrificial porous silicon layer (for example through a mechanical release MR process) while the template may be re-used many times to further minimize solar cell manufacturing cost. Final cell processing may then be performed on the solar cell sunny-side which is exposed after being released from the template. Sunny-side processing may include, for instance, completing frontside texturization and passivation and anti-reflection coating deposition process.

After formation of the backplane (on or in and around M1 layer), subsequent detachment of the backplane-supported solar cell from the template along the mechanically weak sacrificial porous silicon layer, and completion of the frontside texture and passivation processes, a higher conductivity M2 layer is formed on the backplane. Via holes (in some instances up to hundreds or thousands of via holes) are drilled into the backplane (for example by laser drilling) and may have diameters in the range of approximately 50 up to 500 microns. These via holes land on pre-specified regions of Ml for subsequent electrical connections between the patterned M2 and Ml layers through conductive plugs formed in these via holes. Subsequently or in conjunction with the via holes filling and conductive plug formation, the patterned higher-conductivity metallization layer M2 is formed (for example by plasma sputtering, plating, evaporation, or a combination thereof—using an M2 material comprising aluminum, Al/NIV, Al/NiV/Sn, or copper). For an interdigitated back-contact (IBC) solar cell with fine-pitch IBC fingers on M1 (for instance, hundreds of fingers), the patterned M2 layer may be designed orthogonal to M1—in other words rectangular or tapered M2 fingers are essentially perpendicular to the M1 fingers. Because of this orthogonal transformation, the M2 layer may have far fewer IBC fingers than the M1 layer (for instance, by a factor of about 10 to 50 fewer M2 fingers). Hence, the M2 layer may be formed in a much coarser pattern with wider IBC fingers than the M1 layer. Solar cell busbars may be positioned on the M2 layer, and not on the M1 layer (in other words a busbarless M1), to eliminate electrical shading losses associated with on-cell busbars. As both the base and emitter interconnections and busbars may be positioned on the M2 layer on the solar cell backside backplane, electrical access is provided to both the base and emitter terminals of the solar cell on the backplane from the backside of the solar cell.

The backplane material formed between M1 and M2 may be a thin sheet of a prepreg material with sufficiently low coefficient of thermal expansion (CTE) to avoid causing excessive thermally induced stresses on the thin silicon layer. Moreover, the prepreg backplane should meet process integration requirements for the backend cell fabrication processes, in particular chemical resistance during wet texturing of the cell frontside and thermal stability during the PECVD deposition of the frontside passivation and ARC layer. The electrically insulating prepreg backplane material should also meet the module-level lamination process and long-term reliability requirements.

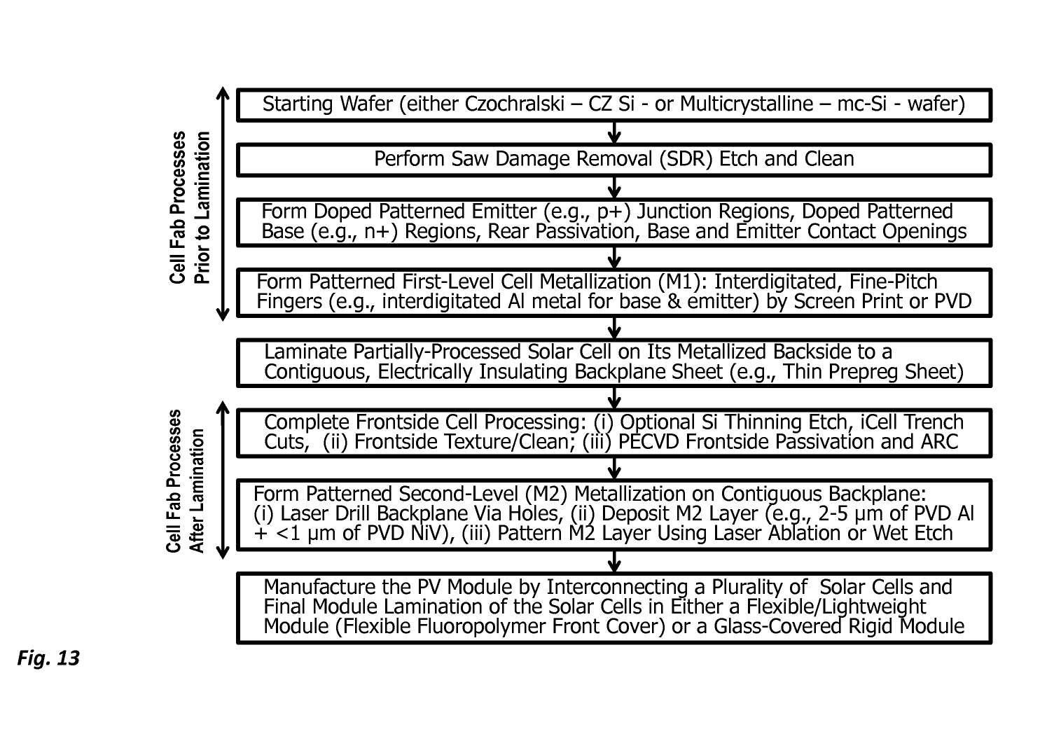

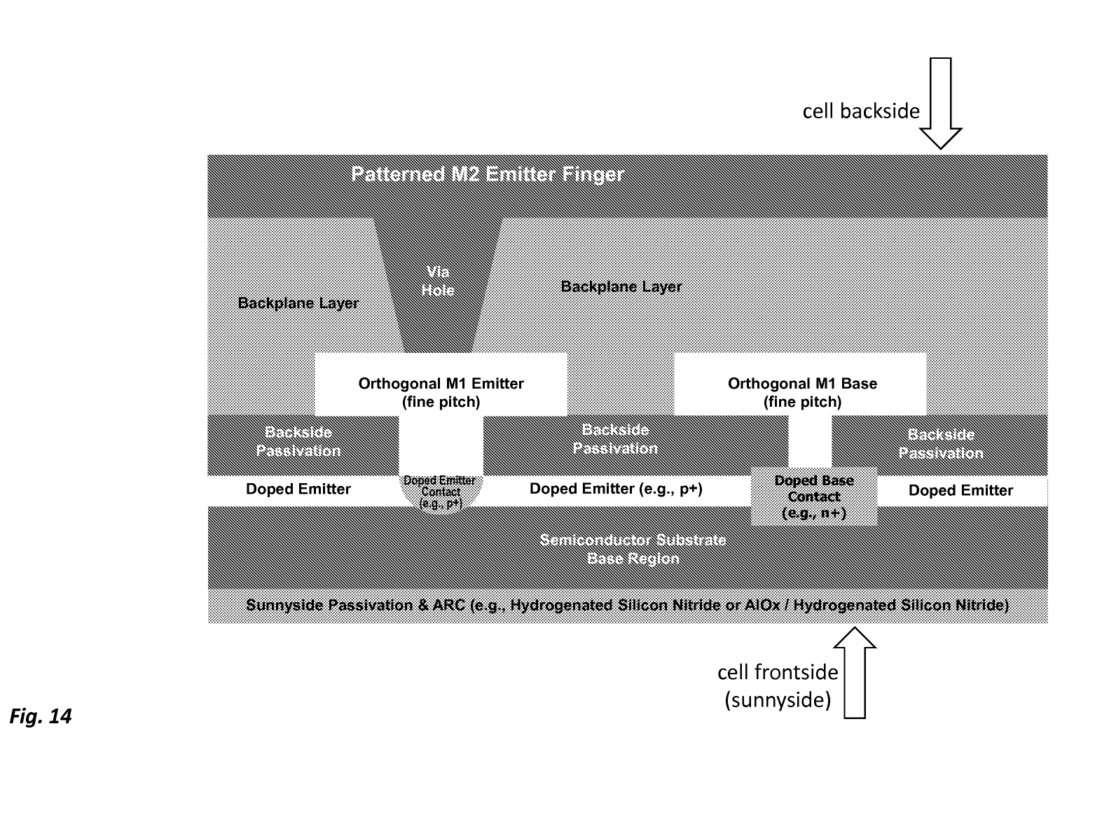

FIG. 13 is a high level solar cell and module fabrication process flow embodiment using starting crystalline (mono-crystalline or multi-crystalline) silicon wafers in accordance with the disclosed subject matter. FIG. 13 shows a high-level icell process flow for fabrication of backplane-attached back-contact/back-junction (IBC) using two layers of metallization: M1 and M2. The first layer or level of patterned cell metallization Ml is formed as essentially the last process step among a plurality of front-end cell fab processes prior to the backplane lamination to the partially processed solar cell. FIG. 14 is a cross-sectional diagram of a solar cell in accordance with the disclosed subject matter and which may be fabricated according the process steps above.

The prepreg sheet may be attached to the solar cell backside while still on the template (before the cell lift off process) using a vacuum laminator. Upon applying heat and pressure, the thin prepreg sheet is permanently laminated or attached to the backside of the processed solar cell. Then, the lift-off release boundary is defined around the periphery of the solar cell (near the template edges), for example by using a pulsed laser scribing tool, and the backplane-laminated solar cell is then separated from the reusable template using a mechanical release or lift-off process. Subsequent process steps may include: (i) completion of the texture and passivation processes on the solar cell sunnyside, (ii) completion of the solar cell high conductivity metallization on the cell backside (which may comprise part of the solar cell backplane). The high-conductivity metallization M2 layer (for example comprising aluminum, copper, or silver) comprising both the emitter and base polarities is formed on the laminated solar cell backplane.

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

What is claimed is:

1. A back contact solar cell structure comprising a sunlight receiving frontside and a metallized backside, further comprising:
on-cell patterned base and emitter metallization electrically connected to base and emitter regions of a back contact solar cell semiconductor substrate backside, portions of said back contact solar cell semiconductor substrate backside not covered by said on-cell patterned base and emitter metallization; and
a backplane laminate layer attached to said patterned on-cell base and emitter metallization and attached to regions of said back contact solar cell substrate backside not covered by said on-cell patterned base and emitter metallization, said backplane laminate comprised of resin and fibers and having a coefficient of thermal expansion relatively closely matched to said back contact solar cell semiconductor substrate.

2. The back contact solar cell structure of claim 1, wherein said backplane laminate layer is a fiber-reinforced prepreg layer.

3. The back contact solar cell structure of claim 1, wherein said fibers in said backplane laminate layer are made of an aramid fiber.

4. The back contact solar cell structure of claim 1, wherein said fiber in said backplane laminate layer includes non-woven aramid fibers.

5. The back contact solar cell structure of claim 1, wherein said fiber in said backplane laminate layer includes woven aramid fibers.

6. The back contact solar cell structure of claim 1, wherein said backplane laminate layer is a semi-rigid backplane having a thickness in the range of approximately 75 μm to 1000 μm.

7. The back contact solar cell structure of claim 1, wherein said backplane laminate layer is a flexible backplane having a thickness in the range of approximately 50 μm to 150 μm.

8. The back contact solar cell structure of claim 1, wherein said backplane laminate layer is a flexible backplane having a thickness in the range of approximately 25 μm to 100 μm.

9. The back contact solar cell structure of claim 1, wherein said resin in said backplane laminate layer is a blended resin comprising at least two different resin components.

10. The back contact solar cell structure of claim 1, wherein said resin in said backplane laminate layer is a blended resin comprising at least one thermoplastic resin component.

11. The back contact solar cell structure of claim 1, wherein said resin in said backplane laminate layer comprises an epoxy or thermoset or B-stage resin.

12. The back contact solar cell structure of claim 1, wherein said backplane laminate further comprises a silane based adhesion promoter.

13. The back contact solar cell structure of claim 1, wherein said back contact solar cell substrate is a crystalline silicon back contact solar cell substrate.

14. The back contact solar cell structure of claim 1, wherein said back contact solar cell substrate is an interdigitated back contact solar cell substrate and said on-cell base and emitter metallization is formed in a pattern of interdigitated base and emitter metallization fingers.

15. The back contact solar cell structure of claim 1, further comprising:
a plurality of via holes drilled in said backplane laminate; and
a second layer of base and emitter metallization formed on said backplane laminate and providing electrical interconnections to said on-cell base and emitter metallization through said via holes in said backplane laminate.

16. A back contact solar cell structure comprising a sunlight receiving frontside and a metallized backside, further comprising:
on-cell patterned base and emitter metallization electrically connected to base and emitter regions of a back contact solar cell semiconductor substrate, portions of said back contact solar cell substrate backside not covered by said on-cell patterned base and emitter metallization; and
a backplane laminate layer attached to said on-cell patterned base and emitter metallization and attached to regions of said back contact solar cell substrate backside not covered by said on-cell patterned base and emitter metallization, said backplane laminate having a first portion comprised of resin and flowed over and between said patterned on-cell base and emitter metallization and attached to said back contact solar cell substrate backside, said backplane laminate having a second portion on said first portion comprised of resin and fiber and providing a thermal expansion control layer with sufficiently low coefficient of thermal expansion (CTE) in combination with and relative to said back contact solar cell semiconductor substrate.

17. The back contact solar cell structure of claim 16, wherein said backplane laminate layer is an electrically insulating layer.

18. The back contact solar cell structure of claim 16, wherein said fiber in said second portion of said backplane laminate layer is an aramid fiber.

19. The back contact solar cell structure of claim 16, wherein said fiber in said second portion of said backplane laminate layer is a non-woven aramid fiber.

20. The back contact solar cell structure of claim 16, wherein said fiber in said second portion of said backplane laminate layer is a woven aramid fiber.

21. The back contact solar cell structure of claim 16, wherein said backplane laminate layer is a rigid backplane having a thickness in the range of approximately 75 μm to 1000 μm.

22. The back contact solar cell structure of claim 16, wherein said backplane laminate layer is a flexible backplane having a thickness in the range of approximately 50 μm to 150 μm.

23. The back contact solar cell structure of claim 16, wherein said backplane laminate layer is a flexible backplane having a thickness in the range of approximately 25 μm to 100 μm.

24. The back contact solar cell structure of claim 16, wherein said resin in said backplane laminate layer is a blended resin comprising at least two resin components.

25. The back contact solar cell structure of claim 16, wherein said resin in said backplane laminate layer is a blended resin comprising at least one thermoplastic resin component.

26. The back contact solar cell structure of claim 16, wherein said resin in said backplane laminate layer comprises an epoxy or thermoset or B-stage resin.

27. The back contact solar cell structure of claim 16, wherein said backplane laminate further comprises a silane based adhesion promoter.

28. The back contact solar cell structure of claim 16, wherein said back contact solar cell substrate is a crystalline silicon back contact solar cell substrate.

29. The back contact solar cell structure of claim 16, wherein said back contact solar cell is an interdigitated back contact solar cell and said on-cell patterned base and emitter metallization is formed in a pattern of interdigitated base and emitter metallization fingers.

30. The back contact solar cell structure of claim 16, further comprising:
a plurality of via holes drilled in said backplane laminate; and
a second layer of base and emitter metallization formed on said backplane laminate and providing electrical interconnections to said on-cell base and emitter metallization through said via holes in said backplane laminate.

31. The back contact solar cell structure of claim 16, wherein said backplane laminate layer has a resin content in the range of 30% to 45%.

32. A micro-electronic semiconductor structure formed on a semiconductor substrate, comprising:
a first layer of patterned metallization electrically connected to select regions of said semiconductor substrate, portions of said semiconductor substrate not covered by said first layer of patterned metallization; and
a backplane laminate layer attached to said first layer of patterned metallization and attached to regions of said semiconductor substrate not covered by said first layer of patterned metallization, said backplane laminate having a first portion comprised of resin and flowed over and between said first layer of patterned metallization and attached to said semiconductor substrate, said backplane laminate having a second portion on said first portion comprised of resin and fiber and providing a thermal expansion control layer with sufficiently low coefficient of thermal expansion (CTE) in combination with and relative to said semiconductor substrate.

33. A semiconductor device structure formed on a semiconductor substrate, comprising:
a first layer of patterned metallization electrically connected to select regions of said semiconductor substrate, portions of said semiconductor substrate not covered by said first layer of patterned metallization; and
a backplane laminate layer attached to said first layer of patterned metallization and attached to regions of said semiconductor substrate not covered by said first layer of patterned metallization, said backplane laminate having a first portion comprised of resin and flowed over and between said first layer of patterned metallization and attached to said semiconductor substrate, said backplane laminate having a second portion on said first portion comprised of resin and fiber and providing a thermal expansion control layer with sufficiently low coefficient of thermal expansion (CTE) in combination with and relative to said semiconductor substrate.

34. A semiconductor device structure formed on a semiconductor substrate, comprising:
a first layer of patterned metallization electrically connected to select regions of said semiconductor substrate, portions of said semiconductor substrate not covered by said first layer of patterned metallization; and
an electrically insulating backplane laminate layer attached to said first layer of patterned metallization and attached to regions of said semiconductor substrate not covered by said first layer of patterned metallization, said backplane laminate having a combination of resin with a coefficient of thermal expansion (CTE) which is relatively closely matched to said semiconductor substrate.

35. The back contact solar cell structure of claim 34 (above), further comprising:
a plurality of via holes drilled in said backplane laminate; and
a second layer of patterned metallization formed on said backplane laminate and providing electrical interconnections to said first layer of patterned metallization through said via holes in said backplane laminate.
